(19) United States
(12) Patent Application Publication
(10) Pub. No.: US 2026/0018450 A1
(43) Pub. Date: Jan. 15, 2026

(54) ELEMENT TRANSFER DEVICE AND ELEMENT TRANSFER METHOD

(71) Applicant: TORAY ENGINEERING CO., LTD., Tokyo (JP)

(72) Inventors: Haruka FUJISHIGE, Ritto-shi (JP); Yoshiyuki ARAI, Otsu-shi (JP); Tatsuya OKADA, Kyoto-shi (JP); Koichi KAZAMA, Otsu-shi (JP); Yuichiro TSUDA, Osaka (JP); Toshiyuki JINDA, Kusatsu-shi (JP); Takumi IKEHARA, Otsu-shi (JP)

(21) Appl. No.: 19/338,146

(22) Filed: Sep. 24, 2025

Related U.S. Application Data
(63) Continuation of application No. PCT/JP2024/012484, filed on Mar. 27, 2024.

(30) Foreign Application Priority Data
Mar. 29, 2023 (JP) 2023-054269
Mar. 29, 2023 (JP) 2023-054310
Mar. 26, 2024 (JP) 2024-050351

(51) Int. Cl. H01L 21/683; B23K 26/08

(52) U.S. Cl. CPC H01L 21/6835; B23K 26/08; H01L 2221/68386

(57) ABSTRACT

An element transfer device includes a support substrate holding part that holds a support substrate on which an element is supported via an adhesive layer, a laser light irradiation unit that is disposed on a side opposite to a surface on which the element is supported by the support substrate and irradiates laser light toward the support substrate, and a control unit that controls an irradiation position of the laser light irradiated from the laser light irradiation unit. An area of a spot area of the laser light is smaller than an area of a surface of the element supported by the support substrate. The control unit controls the irradiation position of the laser light such that the laser light is irradiated from one end side of the element to the other end side while moving relative to the support substrate.

### CROSS-REFERENCE TO RELATED APPLICATIONS

This application is a continuation application of PCT International Application No. PCT/JP2024/012484 filed on Mar. 27, 2024, which claims priority to Japanese Patent Application Nos. 2023-054269 filed on Mar. 29, 2023 with Japan Patent Office, 2023-054310 filed on Mar. 29, 2023 with Japan Patent Office, and 2024-050351 filed on Mar. 26, 2024 with Japan Patent Office. The entire disclosures of PCT International Application No. PCT/JP2024/012484 and Japanese Patent Application Nos. 2023-054269, 2023-054310 and 2024-050351 are hereby incorporated herein by reference.

### BACKGROUND

### Field of the Invention

The present invention generally relates to an element transfer device comprising a laser light irradiation unit that irradiates laser light, and an element transfer method.

### Background Information

Element transfer devices that irradiate laser light from a laser light irradiation unit are known from the prior art (for example, Japanese Unexamined Patent Application Publication (Translation of PCT application) No. 2014-515883 (Patent Document 1)).

The above-mentioned Patent Document 1 discloses a laser transfer device that transfers an article attached to a substrate onto another substrate. In the above-mentioned Patent Document 1, an adhesive layer is provided between the substrate and the article, and the article is held by the adhesive layer. In addition, in the above-mentioned Patent Document1, laser light is irradiated from an upper surface side of the substrate toward the adhesive layer, causing the adhesive layer to bulge downward in a convex shape. As a result, the article is peeled from the adhesive layer and transferred onto another substrate. In addition, in Patent Document 1, the adhesive layer on which the laser light is irradiated toward the center of the article bulges in a relatively large convex shape, so that the article is peeled from the center.

### SUMMARY

However, as described in the above-mentioned Patent Document 1, when an article is peeled from the center, the periphery of the portion that is peeled at the center of the article is in contact with the adhesive layer, which may make it difficult for the article to be peeled. Therefore, there is demand for an element transfer device and an element transfer method with which articles can be easily peeled.

One object of the present disclosure is to provide an element transfer device and an element transfer method with which elements can be easily peeled.

In order to achieve the object described above, an element transfer device according to a first aspect comprises a support substrate holding part configured to hold a support substrate on which an element is supported via an adhesive layer, a laser light irradiation unit disposed on a side opposite to a surface on which the element is supported by the support substrate and configured to irradiate laser light toward the support substrate, and a control unit configured to control an irradiation position of the laser light irradiated from the laser light irradiation unit. An area of a spot area of the laser light is smaller than an area of a surface of the element supported by the support substrate. The control unit is configured to control the irradiation position of the laser light such that, as viewed from a direction perpendicular to a front surface of the support substrate, the laser light is irradiated from one end side of the element to the other end side while moving relative to the support substrate.

As described above, the element transfer device according to the first aspect controls the irradiation position of the laser light such that, as viewed from the direction perpendicular to the front surface of the support substrate, the laser light is irradiated from the one end side of the element to the other end side while moving relative to the support substrate. Here, the effect of the adhesive force of the adhesive layer is smaller when the element is peeled from an end than when the element is peeled from the center. The foregoing is because, at the center, the periphery of the portion to be peeled is in contact with the adhesive layer, whereas at the end the adhesive layer exists only on one side of the portion to be peeled. Therefore, as a result of the control unit controlling the irradiation position of the laser light to move from the one end side of the element to the other end side, peeling begins from an end of the element, making it possible to easily peel the element.

In the element transfer device according to the first aspect described above, the area of the spot area of the laser light is preferably set in accordance with fragility of the element to be transferred. As a result, even when the element is relatively fragile, such as elements having relatively small thickness, the area of the spot area of the laser light is set in accordance with the fragility of the element. For example, when the element is relatively fragile, the area of the spot area of the laser light is adjusted to be relatively small. Therefore, since the area of the spot area of the laser light becomes relatively small, deformation of the adhesive layer also becomes small. As a result, stress on the element caused by deformation of the adhesive layer is reduced, making it possible to prevent the element from being damaged. As a result, it is possible to transfer the element while further suppressing damage to the element caused by deformation of the adhesive layer.

In the element transfer device according to the first aspect described above, the laser light irradiation unit is preferably configured to intermittently irradiate the laser light when the laser light is irradiated while moving relative to the support substrate, and a pitch of irradiation positions of the laser light that is intermittently irradiated is set to become smaller as the element becomes more fragile. Here, when the area of the spot area of the laser light is set to decrease as the element becomes more fragile, if the pitch of the irradiation positions of the laser light remains relatively large, the distance between the portions of the element peeled from the adhesive layer becomes large, and the holding force of the adhesive layer with respect to the entire element remains relatively large. Therefore, by setting the pitch of the irradiation positions of the laser light to decrease as the element becomes more fragile, the distance between the portions of the element peeled from the adhesive layer becomes small, thereby reducing the holding force of the adhesive layer with respect to the entire element. As a result, the element can be appropriately peeled from the adhesive layer.

In the element transfer device according to the first aspect described above, the laser light irradiation unit is preferably configured to intermittently irradiate the laser light when the laser light is irradiated while moving relative to the support substrate, and the control unit is configured to control the irradiation position of the laser light that is intermittently irradiated so as to irradiate a vicinity of a boundary between a portion where the element is peeled from the support substrate due to irradiation of the laser light and a portion where the element remains supported by the support substrate. Here, the holding force of the adhesive layer in the vicinity of the boundary becomes smaller than the holding force of the adhesive layer at unpeeled portions away from the vicinity of the boundary. The foregoing is because, while the periphery of portions to be peeled is in contact with the adhesive layer except in the vicinity of the boundary, the adhesive layer exists only on one side of the portion to be peeled in the vicinity of the boundary. As a result, it is possible to easily peel the element by irradiating the vicinity of the boundary with laser light.

In this case, the control unit is preferably configured to adjust a pitch of irradiation positions of the laser light that is intermittently irradiated to be small at ends of the element and to be large at a center of the element. Here, it has been confirmed through experiments and simulations carried out by the present inventor that the area of the element that is peeled by a single irradiation of laser light becomes larger at the ends of the element than at the center of the element. In addition, it has been confirmed that irradiating laser light onto a portion of an element that has already been peeled does not contribute to further peeling. That is, since the area of the element that is peeled by a single laser irradiation is large at the ends, when subsequently irradiating laser light to the center of the element, the irradiation pitch of the laser light can be increased to more efficiently transfer the element. Thus, the control unit adjusts the pitch of the irradiation positions of the laser light that is intermittently irradiated to be small at the ends of the element and to be large at the center of the element, thereby reducing the time required for the transfer of elements, compared to a case in which the pitch of the irradiation positions of the laser light is decreased across the entire element.

In the element transfer device according to the first aspect described above, the control unit is preferably configured to control the laser light to be irradiated while the laser light moves relative to the support substrate in a first direction from one end side of the element to the other end side as viewed from a direction perpendicular to the front surface of the support substrate, such that the element supported by the support substrate is peeled from the one end side, and one end of the element comes in contact with a receiving substrate before entirety of the element is peeled from the support substrate, after which the entirety of the element is transferred. As a result, the one end of the element comes in contact with the receiving substrate fixing the position thereof, after which the remaining portion is peeled. Therefore, the direction of the shift in the transfer position of the element is controlled to be in a set direction, thereby making it possible to suppress the transfer positions of the elements on the receiving substrate from being scattered in various directions (variation in the transfer positions can be suppressed).

In the element transfer device according to the first aspect described above, the control unit is preferably configured to control the laser light to be irradiated while the laser light moves relative to the support substrate in the first direction, following a zigzag pattern on the surface of the element. With such a configuration, the laser light is moved relatively in the first direction following the zigzag pattern, so that the laser light can be irradiated over the entire surface of the element.

In this case, the element transfer device further comprises a receiving substrate holding part configured to hold the receiving substrate to which the element is transferred, and a movement mechanism configured to move at least one of the support substrate holding part and the receiving substrate holding part. The controller is further configured to acquire a predicted transfer position on the receiving substrate to which the element is transferred, configured to compare the predicted transfer position with a vertical transfer position to which the element is transferred when dropped vertically without being moved in a horizontal direction, to thereby acquire, in advance, a positional deviation amount of a transfer position, and configured to control the movement mechanism such that the at least one of the support substrate holding part and the receiving substrate holding part is moved on the basis of the positional deviation amount. With such a configuration, it becomes possible to adjust in advance the positions of the support substrate and the receiving substrate before the element is actually transferred to the receiving substrate so as to eliminate positional deviation that occurs between the actual transfer position and the vertical transfer position to which the element would be transferred if dropped vertically without being moved in the horizontal direction. As a result, the element can be transferred to a desired position.

In this case, the control unit is preferably configured to acquire, on the basis of the positional deviation amount, a target transfer position that is shifted from the vertical transfer position by an amount equal to the positional deviation amount, and configured to control the movement mechanism to move the at least one of the support substrate holding part and the receiving substrate holding part such that a target transfer position is positioned directly below the element to be transferred. With such a configuration, the support substrate holding part and/or the receiving substrate holding part can be moved in advance on the basis of a transfer position (target transfer position) that takes positional deviation into consideration, so that it is possible to carry out transfer without causing positional deviation.

In the element transfer device comprising the receiving substrate holding part and the movement mechanism described above, the control unit is preferably configured to acquire the predicted transfer position on the receiving substrate to which the element is transferred on the basis of at least a distance between the support substrate and the receiving substrate and a length of the element along a first direction, and configured to compare the predicted transfer position with the vertical transfer position to which the element is transferred when dropped vertically without being moved in the horizontal direction, to thereby acquire, in advance, the positional deviation amount of the transfer position. With such a configuration, it becomes possible to identify, in advance, the amount of positional deviation that occurs between the actual transfer position and the vertical transfer position to which the element would be transferred if dropped vertically without being moved in the horizontal direction, before the element is actually transferred to the receiving substrate.

In this case, the control unit is preferably configured to acquire the predicted transfer position on the receiving substrate to which the element is transferred further on the basis of a thickness of the element, and configured to compare the vertical transfer position and the predicted transfer position, to thereby acquire, in advance, the positional deviation amount. With such a configuration, even when the thickness of the element is too large to ignore relative to the distance between the support substrate and the receiving substrate, it becomes possible to accurately identify, in advance, the amount of positional deviation that occurs between the actual transfer position and the vertical transfer position to which the element would be transferred if dropped vertically without being moved in the horizontal direction.

In the element transfer device in which the laser light moves relatively in the first direction from the one end side of the element to the other end side, preferably, the support substrate held by the support substrate holding part is configured to support a plurality of elements, and the control unit is configured to control the laser light to be irradiated while the laser light moves relative to the support substrate in the first direction, with respect to all of the elements to be transferred supported on the support substrate. With such a configuration, one ends of all of the elements to be transferred supported on the support substrate can be brought into contact with the receiving substrate from the same direction. As a result, the shift in the transfer position of the element is controlled to be in a set direction, thereby making it possible to suppress the transfer positions of the elements on the receiving substrate from being scattered in various directions (variation in the transfer positions can be suppressed).

In the element transfer device according to the first aspect described above, the control unit is preferably configured to start irradiation of the laser light such that only a portion of a blister that is generated due to the laser light being irradiated on the adhesive layer overlaps with the element, as viewed from a direction perpendicular to the front surface of the support substrate. When the element begins to be peeled, the entire surface of the element is in close contact with the adhesive layer. Therefore, when laser light is irradiated on a position where the entire blister overlaps with the element, the total adhesive force acting on the element becomes large, which increases the bending stress acting on the element and may cause damage to the element. Therefore, by irradiating the laser light on a position where only a portion of the blister overlaps with the element, the total adhesive force acting on the element can be reduced, which reduces the bending stress acting on the element, thereby suppressing damage to the element.

In the element transfer device according to the first aspect described above, the laser light irradiation unit is preferably configured to intermittently irradiate the laser light when the laser light is irradiated while moving relative to the support substrate, and the control unit is configured to control the irradiation position of the laser light that is intermittently irradiated such that portions of the element that have been peeled from the support substrate due to the laser light that is intermittently irradiated overlap with each other. With such a configuration, since the portions of the element that have been peeled overlap with each other, the element can be peeled even with intermittent irradiation of the laser light. In addition, even if gaps form between a plurality of peeled portions, the portions of the element that correspond to the gaps will naturally be peeled as the adjacent portions are peeled, so that the element can be peeled even with intermittent irradiation of the laser light.

In the element transfer device according to the first aspect described above, the control unit is preferably configured to control the irradiation position of the laser light that is intermittently irradiated such that small blisters that are generated on the adhesive layer due to the intermittently irradiated laser light coalesce with each other to form a single large blister. With such a configuration, since the blisters coalesce with each other to form the single large blister, the element can be peeled even with intermittent irradiation of the laser light. In addition, since blisters that are generated by the laser light are small, the stress acting on the element can be reduced. As a result, damage to the element can be further suppressed.

In the element transfer device according to the first aspect described above, preferably, a force with which a blister, generated due to the laser light being irradiated on the adhesive layer, presses the element and a radius of a peeled range of the element are set such that σpeel<σmax<σb is satisfied by adjusting the area and energy of the spot area of the laser light, where σpeel represents a minimum stress applied to the element when being peeled from the adhesive layer, σmax represents a maximum bending stress applied to the element and is defined as σmax=P×(1+ν)×(0.485×ln(R/t)+0.52)/t², where P represents the force with which the blister, generated due to the laser light being irradiated on the adhesive layer, presses the element, R represents the radius of the peeled range of the element, t represents a thickness of the element, and ν represents Poisson's ratio, and σb represents flexural strength of the element. With such a configuration, it is possible to easily adjust the area and energy of the spot area of the laser light so that damage to the element can be suppressed, on the basis of the relationship described above.

An element transfer method according to a second aspect comprises irradiating laser light toward a support substrate on which an element is supported via an adhesive layer from a side opposite to a surface on which the element is supported by the support substrate. The irradiating of the laser light includes adjusting the laser light such that an area of a spot area of the laser light is smaller than an area of a surface of the element supported by the support substrate, and irradiating the laser light such that, as viewed from a direction perpendicular to a front surface of the support substrate, the laser light is irradiated from one end side of the element to the other end side while moving relative to the support substrate.

In the element transfer method according to the second aspect, as described above, the irradiating of the laser light includes adjusting the laser light such that the area of the spot area of the laser light is smaller than the area of the surface of the element supported by the support substrate, and irradiating the laser light such that, as viewed from the direction perpendicular to the front surface of the support substrate, the laser light is irradiated from the one end side of the element to the other end side while moving relative to the support substrate. Here, the effect of the adhesive force of the adhesive layer is smaller when an element is peeled from an end than when an element is peeled from the center. The foregoing is because, at the center, the periphery of the portion to be peeled is in contact with the adhesive layer, whereas at the end the adhesive layer exists only on one side of the portion to be peeled. Therefore, as a result of the control unit controlling the irradiation position of the laser light to move from one end side of the element to the other end side, peeling begins from an end of the element, making it possible to provide an element transfer method by which the element can be easily peeled.

In the element transfer method according to the second aspect, preferably, the laser light is irradiated while moving relative to the support substrate in a first direction from the one end side of the element to the other end side as viewed from the direction perpendicular to the front surface of the support substrate, such that the element supported by the support substrate is peeled from the one end side of the element, and one end of the element comes in contact with, and is transferred to, a receiving substrate before entirety of the element is peeled from the support substrate. As a result, the one end of the element comes in contact with the receiving substrate fixing the position thereof, after which the remaining portion is peeled. As a result, the shift in the transfer position of the element is controlled to be in a set direction, thereby making it possible to suppress the transfer positions of the elements on the receiving substrate from being scattered in various directions (variation in the transfer positions can be suppressed).

In this case, the element transfer method preferably further comprises acquiring a predicted transfer position on the receiving substrate to which the element is transferred on the basis of at least a distance between the support substrate and the receiving substrate and a length of the element along the first direction, and comparing the predicted transfer position with a vertical transfer position to which the element is transferred when dropped vertically without being moved in a horizontal direction, to thereby acquire a positional deviation amount of a transfer position. With such a configuration, it becomes possible to provide an element transfer method that can identify, in advance, the amount of positional deviation that occurs between the actual transfer position and the vertical transfer position to which the element would be transferred if dropped vertically without being moved in the horizontal direction, before the element is actually transferred to the receiving substrate.

In the element transfer method described above, the acquiring of the predicted transfer position further includes acquiring, on the basis of a thickness of the element, the predicted transfer position on the receiving substrate to which the element is transferred. With such a configuration, it becomes possible to provide an element transfer method in which, even when the thickness of the element is too large to ignore relative to the distance between the support substrate and the receiving substrate, it is possible to accurately identify, in advance, the amount of positional deviation that occurs between the actual transfer position and the vertical transfer position to which the element would be transferred if dropped vertically without being moved in the horizontal direction.

In this case, the element transfer method preferably further comprises relatively moving the support substrate and the receiving substrate by moving at least one of the support substrate and the receiving substrate on the basis of the positional deviation amount. With such a configuration, it becomes possible to adjust in advance the positions of the support substrate and the receiving substrate before the element is actually transferred to the receiving substrate so as to eliminate positional deviation that occurs between the actual transfer position and a vertical transfer position to which the element would be transferred if dropped vertically without being moved in the horizontal direction. As a result, it is possible to provide an element transfer method that can transfer an element to a target position.

In the element transfer method preferably further comprising acquiring a target transfer position that is shifted from the vertical transfer position by an amount equal to the positional deviation amount on the basis of the positional deviation amount, the moving step of the at least one of the support substrate and the receiving substrate includes moving the at least one of the support substrate and the receiving substrate such that the target transfer position is positioned directly below the element to be transferred. With such a configuration, it is possible to provide an element transfer method in which the support substrate and/or the receiving substrate can be moved in advance on the basis of a transfer position that takes positional deviation into consideration, so that it is possible to carry out transfer without causing positional deviation.

As described above, according to the element transfer device and the element transfer method of the present disclosure, elements can be easily peeled.

### BRIEF DESCRIPTION OF THE DRAWINGS

FIG. 1 is a schematic diagram showing an overall configuration of a semiconductor chip transfer device according to a first embodiment.

FIG. 2 is a schematic diagram showing a configuration in which a semiconductor chip is supported on a support substrate.

FIG. 3 is a side view of a semiconductor chip transfer device according to the first embodiment.

FIG. 4 is a diagram explaining a spot area of laser light.

FIG. 5 is a diagram showing a blister when the spot area of the laser light is large.

FIG. 6 is a diagram showing a blister when the spot area of the laser light is small.

FIG. 7 is a diagram showing the relationship between the thickness of a semiconductor chip, and the stress that the semiconductor chip can withstand, the spot area, irradiation pitch of the laser light, the thickness of an adhesive layer, and adhesive force.

FIG. 8 is a diagram explaining a state in which a semiconductor chip is transferred.

FIG. 9 is a diagram showing a boundary between a portion of a semiconductor chip that has peeled from a support substrate, and a portion where a state in which the semiconductor chip is supported by the support substrate is maintained.

FIG. 10 is a schematic diagram showing an overall configuration of a semiconductor chip transfer device according to a second embodiment.

FIG. 11 is a flowchart explaining a process of a semiconductor chip transfer method according to the second embodiment.

FIG. 12 is a diagram showing a start position of laser light irradiation according to a third embodiment.

FIG. 13 is a diagram showing a portion of a semiconductor chip that has been peeled according to a fourth embodiment.

FIG. 14 is a diagram showing an irradiation path of laser light according to a fifth embodiment.

FIG. 15 is a diagram showing a large blister and a small blister generated by irradiation of laser light according to the fifth embodiment.

FIG. 16 is a diagram showing two large blisters generated by irradiation of laser light according to the fifth embodiment.

FIG. 17 is a diagram showing a semiconductor chip and a blister generated by irradiation of laser light according to a sixth embodiment.

FIG. 18A is a diagram showing a model of an adhesive layer and a semiconductor chip according to the sixth embodiment.

FIG. 18B is a partially enlarged view of the diagram shown in FIG. 18A.

FIG. 19 is a diagram showing the relationship between maximum bending strength, and the thickness and flexural strength of a semiconductor chip according to the sixth embodiment.

FIG. 20 is a graph showing the relationship between minimum stress, maximum bending strength, and flexural strength according to the sixth embodiment.

FIG. 21 is a flowchart explaining a process of a transfer method according to a seventh embodiment.

FIG. 22 is a diagram explaining a method for acquiring an amount of positional deviation of a semiconductor chip in a semiconductor chip transfer device according to the seventh embodiment.

FIG. 23 is a diagram showing a configuration for acquiring the distance between a support substrate and a receiving substrate in a semiconductor chip transfer device according to the seventh embodiment.

FIG. 24 is a diagram explaining an operation for adjusting the transfer position of a semiconductor chip on the basis of the positional deviation amount in the semiconductor chip transfer device according to the seventh embodiment.

FIG. 25 is a schematic diagram explaining a state in which laser light is irradiated moving from one end side in a first direction in the semiconductor chip transfer device according to the seventh embodiment.

FIG. 26 is a diagram explaining a state in which a semiconductor chip is peeled from one end side, and one end comes in contact with a receiving substrate, in the semiconductor chip transfer device according to the seventh embodiment.

FIG. 27 is a diagram explaining a state in which laser light is irradiated onto a semiconductor chip in the semiconductor chip transfer device according to the seventh embodiment.

FIG. 28 is a diagram explaining a method for acquiring an amount of positional deviation of a thick semiconductor chip in a semiconductor chip transfer device according to an eighth embodiment.

FIG. 29 is a diagram explaining a method for acquiring a target transfer position of a semiconductor chip on the basis of the positional deviation amount in a semiconductor chip transfer device according to a ninth embodiment.

FIG. 30 is a diagram explaining an operation for adjusting the transfer position of a semiconductor chip on the basis of the positional deviation amount in the semiconductor chip transfer device according to the ninth embodiment.

FIG. 31 is a diagram explaining a state in which laser light is irradiated onto a semiconductor chip in a semiconductor chip transfer device according to a first modified example.

FIG. 32 is a diagram explaining a state in which laser light is irradiated onto a semiconductor chip in a semiconductor chip transfer device according to a second modified example.

### DETAILED DESCRIPTION OF EMBODIMENTS

Specific embodiments of the present disclosure will be described below with reference to the drawings.

### First Embodiment

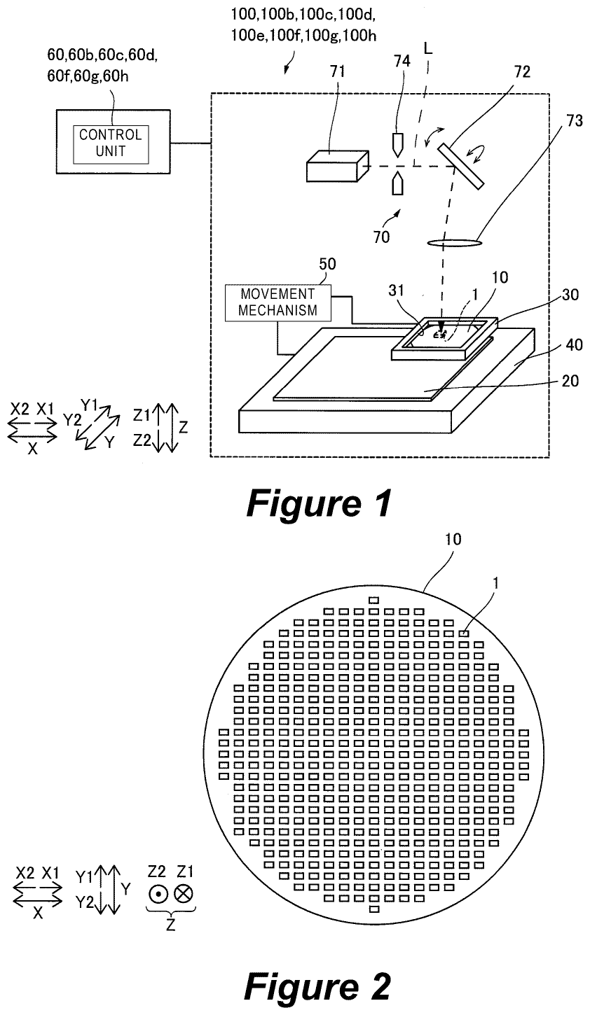

The configuration of a semiconductor chip transfer device 100 according to the first embodiment will be described with reference to FIGS. 1 and 2. The semiconductor chip transfer device 100 is one example of an “element transfer device” in the present disclosure.

### (Semiconductor Chip Transfer Device)

As shown in FIG. 1, the semiconductor chip transfer device 100 is configured to transfer a semiconductor chip 1 that is supported on a support substrate 10 onto a receiving substrate 20 by a laser lift-off method.

The semiconductor chip transfer device 100 comprises a support substrate holding part 30, a receiving substrate holding part 40, a movement mechanism 50, a control unit 60, and a laser light irradiation unit 70. In the diagram, the left-right direction of the semiconductor chip transfer device 100 (one direction in a horizontal plane) is defined as the X direction. In addition, the up-down direction (vertical direction) of the semiconductor chip transfer device 100 is defined as the Z direction. Additionally, the upward direction is defined as the Z1 direction and the downward direction is defined as the Z2 direction. In addition, the direction orthogonal to the X direction and the Z direction of the semiconductor chip transfer device 100 (the other direction in the horizontal plane) is defined as the Y direction.

As shown in FIG. 2, the semiconductor chip 1 is, for example, a thin, rectangular element with one side measuring about several hundred μm to several tens mm, such as a memory unit. However, the semiconductor chip 1 is not limited to thin elements such as a memory unit, and various semiconductor elements may be used. In addition, the semiconductor chip 1 is one example of an “element” in the present disclosure.

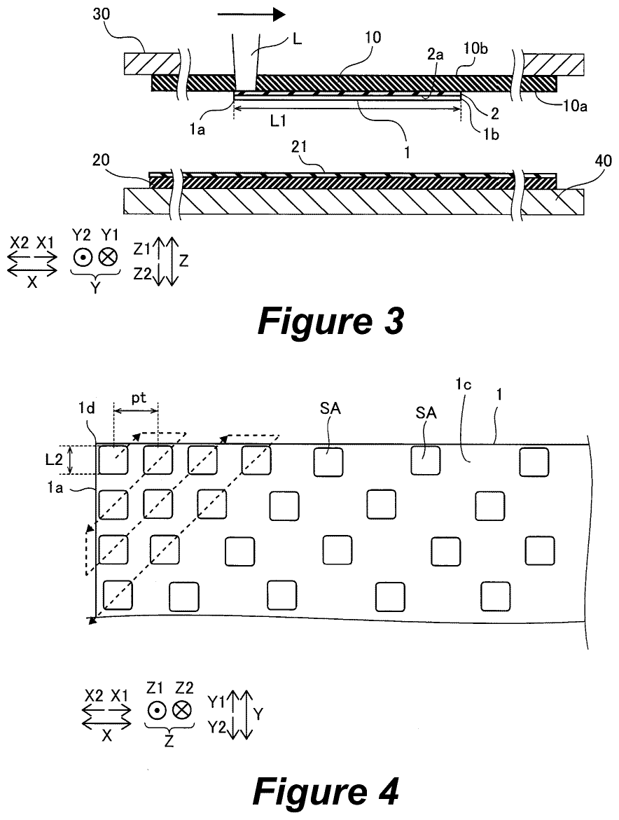

As shown in FIG. 3, the support substrate 10 is formed of a material that transmits laser light L, such as a SiO2 (silicon dioxide) substrate or a sapphire substrate. The support substrate 10 supports the semiconductor chip 1 via an adhesive layer 2. In addition, the support substrate 10 supports a plurality of the semiconductor chips 1 via the adhesive layer 2. The adhesive layer 2 is also referred to as a transfer material.

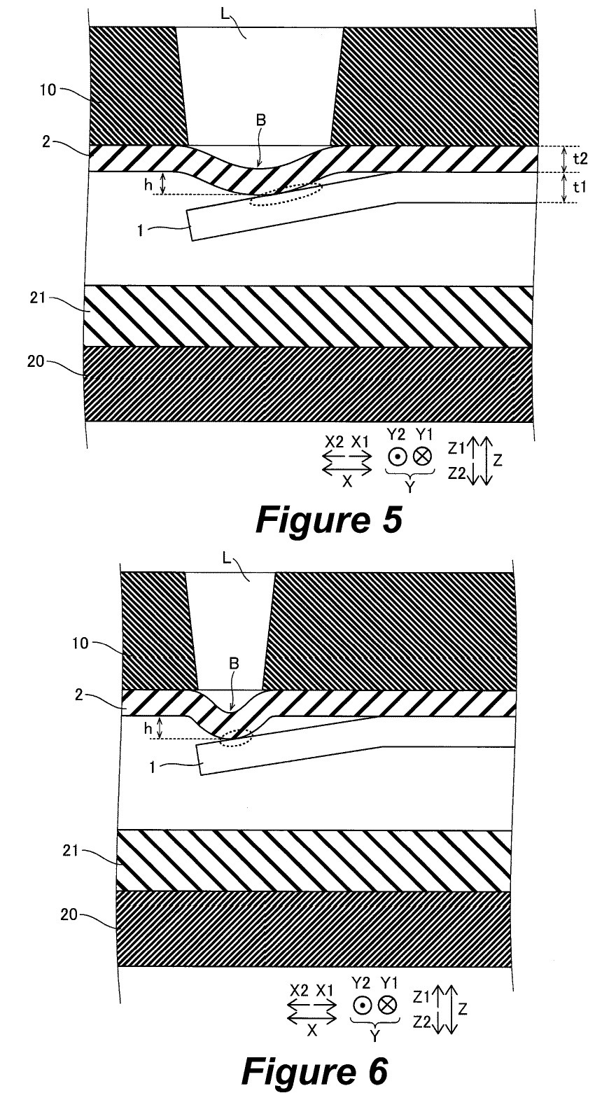

The adhesive layer 2 is disposed on a surface 10a of the support substrate 10 on the Z2 side. The plurality of semiconductor chips 1 are held on a surface 2a of the adhesive layer 2 on the Z2 side. As shown in FIG. 2, the plurality of semiconductor chips 1 are arranged in a matrix at prescribed intervals on the support substrate 10 via the adhesive layer 2. The support substrate 10 has a circular shape. The adhesive layer 2 is formed of a material that is decomposed and generates a gas component as a result of being irradiated with laser light L from the laser light irradiation unit 70. As a result of the generation of the gas component, the adhesive layer 2 deforms in a convex shape protruding toward the Z2 side (refer to FIGS. 5 and 6). For example, polyimide or silicon is used as the adhesive layer 2.

As shown in FIG. 1, the support substrate holding part 30 holds the support substrate 10 on which the semiconductor chip 1 is supported. The support substrate holding part 30 holds the support substrate 10 supporting the semiconductor chip 1 with the surface supporting the semiconductor chip 1 facing downward. The support substrate holding part 30 has an opening 31. The support substrate 10 held by the support substrate holding part 30 is irradiated with laser light L emitted from the laser light irradiation unit 70 via the opening 31. The support substrate holding part 30 is configured to be movable by the movement mechanism 50 relative to the receiving substrate holding part 40 in at least the X and Y directions. In the illustrated embodiment, the support substrate holding part 30 is a plate-like or frame-like member for holding the support substrate 10, and includes a base, a stage or a chuck, for example. In the illustrated embodiment, the movement mechanism 50 has a cross-table structure or stage that is operatively coupled to the control unit 60. This cross-table structure includes an X-axis stage that is movably supported on a base or main body of the semiconductor chip transfer device 100 by a linear guide with a rail and a slider, and a Y-axis stage that is movably supported on the X-axis stage by another linear guide arranged orthogonally. In the illustrated embodiment, the support substrate holding part 30 is supported on the Y-axis stage. Alternatively, the order may be reversed such that the Y-axis stage is supported on the base and the X-axis stage is mounted on the Y-axis stage. In either case, each stage is driven along its linear guide by a drive source such as a ball screw mechanism with a servo motor or a linear motor.

As shown in FIG. 3, the receiving substrate 20 is a substrate used for manufacturing semiconductor products by a large number of the semiconductor chips 1 on the support substrate 10 being transferred onto the receiving substrate 20, for example An adhesive layer 21 for adhering the transferred semiconductor chip 1 is formed on the receiving substrate 20. The adhesive layer 21 is also referred to as a capture layer. In addition, wiring that can be electrically connected to the transferred semiconductor chip 1 may be formed on the receiving substrate 20. The receiving substrate 20 has a rectangular shape.

The receiving substrate holding part 40 holds, from below (Z2 side), the receiving substrate 20 onto which the semiconductor chip 1 supported on the support substrate 10 is to be transferred. The receiving substrate holding part 40 is configured to be movable by the movement mechanism 50 relative to the support substrate holding part 30 in at least the X and Y directions. The movement mechanism 50 may be individually provided to each of the support substrate holding part 30 and the receiving substrate holding part 40. As a result of the movement of the support substrate holding part 30 and/or the movement of the receiving substrate holding part 40 being carried out by the movement mechanism 50, it is possible to adjust the relative position of the semiconductor chip 1 arranged on the support substrate 10 with respect to the receiving substrate 20. In the illustrated embodiment, the receiving substrate holding part 40 is a plate-like member for holding the receiving substrate 20, and includes a base, a stage or a chuck, for example. In the illustrated embodiment, the movement mechanism 50 has an additional cross-table structure or stage that is operatively coupled to the control unit 60. This additional cross-table structure includes an X-axis stage that is movably supported on a base or main body of the semiconductor chip transfer device 100 by a linear guide with a rail and a slider, and a Y-axis stage that is movably supported on the X-axis stage by another linear guide arranged orthogonally. In the illustrated embodiment, the receiving substrate holding part 40 is supported on the Y-axis stage. Alternatively, the order may be reversed such that the Y-axis stage is supported on the base and the X-axis stage is mounted on the Y-axis stage. In either case, each stage is driven along its linear guide by a drive source such as a ball screw mechanism with a servo motor or a linear motor.

As shown in FIG. 1, the control unit 60 is composed of a processor such as a central processing unit (CPU), and carries out various controls by executing a program (software). The control unit 60 selects any of the semiconductor chips 1 within a transfer area and controls the laser light irradiation unit 70 to irradiate laser light L thereon, thereby transferring the selected semiconductor chip 1 onto the receiving substrate 20. In addition, the control unit 60 controls the operation of the movement mechanism 50 and the opening and closing operation of a slit 74.

The laser light irradiation unit 70 is configured to irradiate the support substrate 10 with laser light L. The laser light irradiation unit 70 has a laser light source 71, a galvanometer mirror 72, and an f-θ lens 73. The laser light source 71 is a light source that emits laser light L. The galvanometer mirror 72 can be rotated about two intersecting axes, and reflects laser light L at a given angle. The f-θ lens 73 focuses the laser light L from the galvanometer mirror 72 onto a transfer area on the support substrate 10. Accordingly, the size of the transfer area arranged on the support substrate 10 fits within the irradiation range of the laser light L that is reflected within the rotatable range of the galvanometer mirror 72.

In addition, the slit 74 is provided between the laser light source 71 and the galvanometer mirror 72. The area of a spot area SA (refer to FIG. 4) of the laser light L is adjusted by adjusting the size of the slit 74. A spot area SA means the area of the focal point when the laser light L is focused.

The laser light irradiation unit 70 irradiates, via the galvanometer mirror 72 and the f-θ lens 73, laser light L onto a surface 10b (refer to FIG. 3) on the side opposite to the surface 10a of the support substrate 10 supporting the semiconductor chip 1, the support substrate 10 being held by the support substrate holding part 30. The laser light L is irradiated onto the selected semiconductor chip 1 in the transfer area by the galvanometer mirror 72 and the f-θ lens 73. As a result of the laser light L being irradiated onto the adhesive layer 2 via the support substrate 10, the semiconductor chip 1 is peeled from the support substrate 10 and the semiconductor chip 1 is transferred from the support substrate 10 to the receiving substrate 20. That is, transfer is carried out by the laser lift-off method. The surface 10b of the support substrate 10 is one example of a “front surface” in the present disclosure.

Here, in the first embodiment, as shown in FIG. 4, the area of the spot area SA of the laser light L is smaller than the area of a surface 1c of the semiconductor chip 1 supported by the support substrate 10, and is set in accordance with the fragility of the semiconductor chip 1. Specifically, the area of the spot area SA of the laser light L is adjusted (set) to become smaller as the thickness t1 (refer to FIGS. 5 and 6) of the semiconductor chip 1 decreases. The thickness t1 of the semiconductor chip 1 is, for example 100 μm or less. In addition, the semiconductor chip 1 has a rectangular shape, for example, and the length L1 (refer to FIG. 3) of one side of the semiconductor chip 1 is several tens of μm to several mm, inclusive. In addition, the spot area SA has a rectangular shape, for example, and the length L2 of one side of the spot area SA is several μm to several tens of μm, inclusive. The area of the spot area SA is adjusted to be sufficiently smaller than the area of the semiconductor chip 1.

Here, as shown in FIGS. 5 and 6, when the adhesive layer 2 is irradiated with the laser light L, the adhesive layer 2 deforms in a convex shape protruding toward the Z2 side. FIG. 5 shows a state of the deformed adhesive layer 2 when the area of the spot area SA of the laser light L is large, and FIG. 6 shows a state of the deformed adhesive layer 2 when the area of the spot area SA of the laser light L is small. As shown in FIG. 5, when the area of the spot area SA of the laser light L is large, a blister B, which is the deformed portion of the adhesive layer 2, becomes large. As shown in FIG. 6, when the area of the spot area SA of the laser light L is small, the area of the blister B as viewed from the Z direction becomes relatively small. As shown in FIGS. 5 and 6, when the output (output density) of the same laser light L is equal, the height h of the blister B is smaller in FIG. 6 in which the area of the spot area SA of the laser light L is smaller. The blister B applies bending stress on the semiconductor chip 1. When the height h of the blister B is small, the bending stress acting on the semiconductor chip 1 is smaller when the area of the spot area SA of the laser light L is smaller, as shown in FIG. 6. As a result, the semiconductor chip 1 is less likely to be damaged when the area of the spot area SA of the laser light L is made smaller.

In addition, when the area of the spot area SA of the laser light L is small, as shown in FIG. 6, the blister B becomes smaller, and, compared to the blister B shown in FIG. 5, the contact area between the semiconductor chip 1 and the adhesive layer 2 becomes smaller. As a result, the holding force with which the adhesive layer 2 holds the semiconductor chip 1 becomes small, and thus the semiconductor chip 1 is more easily peeled from the adhesive layer 2 when the area of the spot area SA of the laser light L is small, as shown in FIG. 6. In FIGS. 5 and 6, the areas surrounded by the dotted circles represent the portions where the semiconductor chip 1 and the adhesive layer 2 are in contact.

Additionally, if the output of the laser light L is reduced in a state in which the area of the spot area SA of the laser light L is large, as shown in FIG. 5, the height h of the blister B becomes small, and the contact area between the semiconductor chip 1 and the adhesive layer 2 becomes small. However, if the output of the laser light L is made too small, gas component is not generated in the adhesive layer 2, and thus the blister B is not generated. Therefore, the semiconductor chip 1 is not transferred. That is, adjusting the area of the spot area SA of the laser light L to become smaller as the thickness t1 of the semiconductor chip 1 decreases is effective in the point of transferring the semiconductor chip 1 while suppressing damage to the semiconductor chip 1.

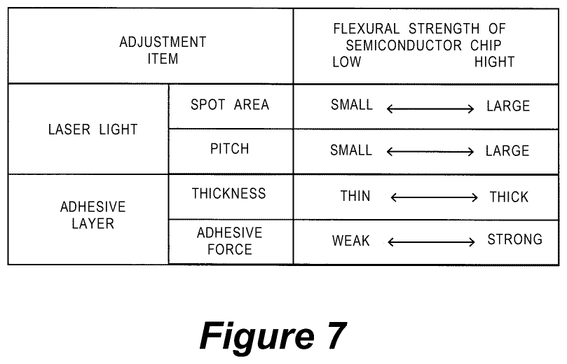

In addition, in the first embodiment, the adjustment (setting) of the area of the spot area SA of the laser light L is carried out by an operator. As shown in FIG. 7, according to experiments and simulations carried out by the present inventor, it was found that damage to the semiconductor chip 1 is suppressed by reducing the area of the spot area SA of the laser light L as the flexural strength of the semiconductor chip 1 decreases. Flexural strength is one example of an index representing the fragility of the semiconductor chip 1. In addition, flexural strength means the value of internal stress that is generated when the semiconductor chip 1 breaks during a bending test of the semiconductor chip 1. In other words, flexural strength means the bending fracture strength of the semiconductor chip 1. In addition, the flexural strength of the semiconductor chip 1 is determined on the basis of factors such as the material, crystal orientation, surface roughness, and aspect ratio (thickness/area, length/area) of the semiconductor chip 1. Specifically, the present inventor found that damage to the semiconductor chip 1 is suppressed by reducing the area of the spot area SA of the laser light L as the thickness t1 of the semiconductor chip 1 decreases. Therefore, in the first embodiment, the operator sets the area of the spot area SA of the laser light L in accordance with the fragility of the semiconductor chip 1, on the basis of the results of the experiments and simulations carried out by the present inventor. Specifically, the operator adjusts (sets) the area of the spot area SA of the laser light L in accordance with the thickness t1 of the semiconductor chip 1 such that damage to semiconductor chips would be suppressed. Even when the area of the spot area SA cannot be changed in the semiconductor chip transfer device 100, if the area of the spot area SA of the laser light L is relatively small, it is possible to transfer the semiconductor chips 1 having various thicknesses t1.

In addition, through experiments and simulations carried out by the present inventor, the present inventor found that damage to the semiconductor chip 1 is suppressed by reducing the thickness t2 of the adhesive layer 2 (refer to FIG. 5) as the flexural strength of the semiconductor chip 1 decreases. Specifically, the present inventor found that damage to the semiconductor chip 1 is suppressed by reducing the thickness t2 of the adhesive layer 2 (refer to FIG. 5) as the thickness t1 of the semiconductor chip 1 decreases. That is, it was found that, when the thickness t2 of the adhesive layer 2 is large, stress caused by deformation of the adhesive layer 2 (generation of the blister B) increases, thereby damaging the semiconductor chip 1.

In addition, through experiments and simulations carried out by the present inventor, the present inventor found that damage to the semiconductor chip 1 is suppressed by reducing the adhesive force of the adhesive layer 2 as the flexural strength of the semiconductor chip 1 decreases. Specifically, the present inventor found that damage to the semiconductor chip 1 is suppressed by reducing the adhesive force of the adhesive layer 2 as the thickness t1 of the semiconductor chip 1 decreases. That is, it was found that, when the adhesive force of the adhesive layer 2 is large, stress caused by deformation of the adhesive layer 2 (generation of the blister B) increases, thereby damaging the semiconductor chip 1.

In addition, in the first embodiment, as shown in FIG. 1, the control unit 60 controls the irradiation position of the laser light L that is irradiated from the laser light irradiation unit 70. Specifically, the control unit 60 rotates the galvanometer mirror 72 to control the irradiation position of the laser light L that is irradiated from the laser light irradiation unit 70. In addition, as shown in FIG. 4, the control unit 60 controls the irradiation position of the laser light L such that, as viewed from a direction (Z direction) perpendicular to the surface 10b of the support substrate 10, the laser light L is irradiated from one end 1a side of the semiconductor chip 1 to the other end 1b side (X1 side) while moving relative to the support substrate 10. In the example shown in FIG. 4, the semiconductor chip 1 has a rectangular shape. The control unit 60 starts the irradiation of laser light L such that the laser light L is irradiated on a corner 1d of the semiconductor chip 1. Thereafter, the control unit 60 controls the irradiation position of the laser light L such that the irradiation position of the laser light L moves to a corner diagonally opposite to the corner 1d, following a zigzag pattern. In FIG. 4, the trajectory of the movement of the laser light L is represented by the dotted lines with arrows.

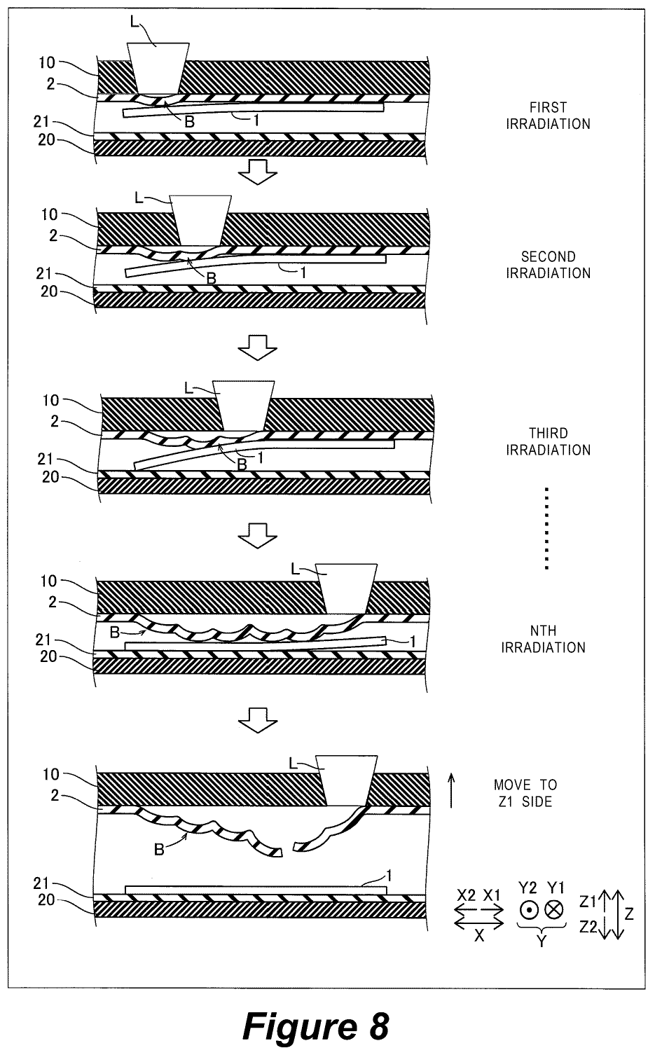

In addition, in the first embodiment, as shown in FIG. 4, the laser light irradiation unit 70 is configured to cause the laser light L to be intermittently irradiated while moving relative to the support substrate 10, when the laser light L is irradiated moving relative to the support substrate 10. For example, the control unit 60 controls the irradiation position of the laser light L such that spot areas SA of the laser light L do not overlap with each other. As a result, as shown in FIG. 8, as the irradiation of the laser light L is sequentially carried out from the first irradiation to the Nth irradiation, a plurality of the blisters B are generated in a scale-like shape and connect to each other, from one end 1a side of the semiconductor chip 1 to the other end 1b side. As a result, the entire area of the semiconductor chip 1 is held by the adhesive layer 21 of the receiving substrate 20. Thereafter, the movement mechanism 50 moves the support substrate 10 in the Z1 direction side, and the semiconductor chip 1 is peeled from the adhesive layer 2 of the support substrate 10. In FIG. 8, the laser light L is illustrated as moving along the X direction, but in reality, as shown in FIG. 4, the laser light L moves within the X-Y plane following a zigzag pattern.

In addition, in the first embodiment, as shown in FIG. 4, the control unit 60 adjusts the pitch pt of the irradiation positions of the laser light L that is intermittently irradiated to be small at the ends of the semiconductor chip 1 and to be large at the center of the semiconductor chip 1. For example, the control unit 60 controls the galvanometer mirror 72 to control the irradiation position of the laser light L such that the pitch pt of the irradiation positions of the laser light L is small at the ends of the semiconductor chip 1 and large at the center of the semiconductor chip 1. The pitch pt of the irradiation positions of the laser light L is made to be small at one end 1a side of the semiconductor chip 1, large at the center of the semiconductor chip 1, and small at the other end 1b side of the semiconductor chip 1. Alternatively, the pitch pt of the irradiation positions of the laser light L may be made to be small at one end 1a side of the semiconductor chip 1, large at the center of the semiconductor chip 1, and also large at the other end 1b side of the semiconductor chip 1. The reason for the foregoing is because, as the peeling of the semiconductor chip 1 progresses, peeling also progresses due to the weight of the peeled portion of the semiconductor chip 1. Therefore, the semiconductor chip 1 is peeled even if a state in which the pitch pt of the irradiation positions of the laser light L stays large at the other end 1b side of the semiconductor chip 1. In addition, the pitch pt of the irradiation positions is the center-to-center distance between spot areas SA of the laser light L that are adjacent to each other in the X direction. In addition, the area of the spot area SA of the laser light L that is intermittently irradiated is constant from one end 1a side of the semiconductor chip 1 to the other end 1b side.

Additionally, in the first embodiment, as shown in FIG. 7, the pitch pt of the irradiation positions of the laser light L that is intermittently irradiated is set to become smaller as the semiconductor chip 1 becomes more fragile. Specifically, the control unit 60 adjusts the pitch pt of the irradiation positions of the laser light L that is intermittently irradiated to become smaller as the flexural strength of the semiconductor chip 1 decreases. In addition, the control unit 60 adjusts the pitch pt of the irradiation positions of the laser light L that is intermittently irradiated to become smaller as the thickness t1 of the semiconductor chip 1 decreases. When the area of the spot area SA of the laser light L is adjusted to be smaller as the thickness t1 of the semiconductor chip 1 decreases, if the pitch pt of the irradiation positions of the laser light L remains relatively large, the distance between portions of the semiconductor chip 1 that have peeled from the adhesive layer 2 becomes larger. In other words, the distance between the blisters B increases. Therefore, the adhesive force of the adhesive layer 2 remains relatively high with respect to the entire semiconductor chip 1. Thus, the control unit 60 controls the irradiation position of the laser light L such that the pitch pt of the irradiation positions of the laser light L decreases as the area of the spot area SA of the laser light L decreases, and also decreases as the thickness t1 of the semiconductor chip 1 decreases.

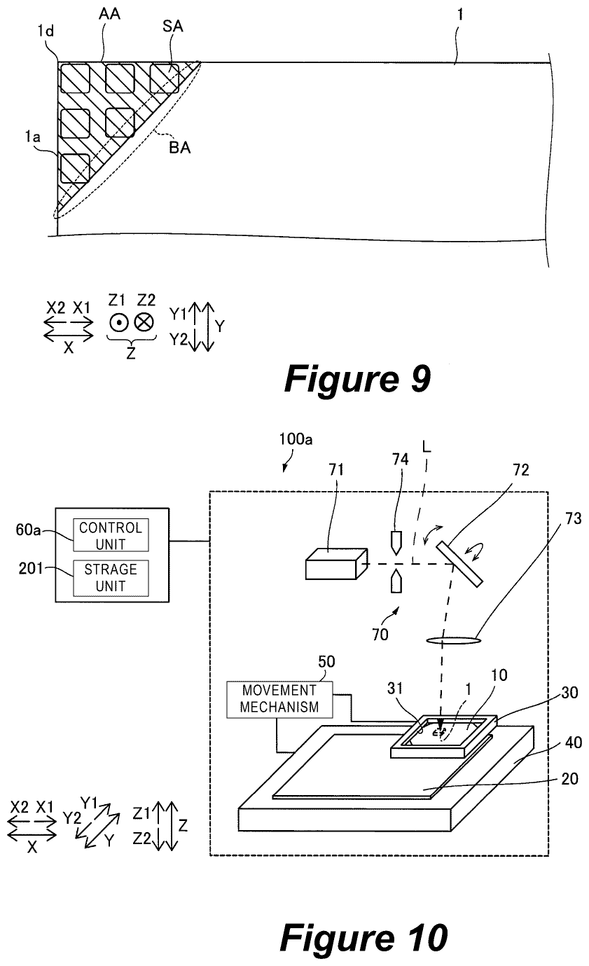

In addition, in the first embodiment, as shown in FIG. 9, the control unit 60 controls the irradiation position of the laser light L that is intermittently irradiated so as to irradiate a vicinity of a boundary BA between a portion where the semiconductor chip 1 has peeled from the support substrate 10 due to the irradiation of the laser light L and a portion where the semiconductor chip 1 remains supported by the support substrate 10. When irradiation of laser light L is started such that the laser light L is irradiated on the corner 1d of the semiconductor chip 1, a triangular area AA (area indicated by the hatching) having the corner 1d of the semiconductor chip 1 as a vertex is peeled from the adhesive layer 2 (support substrate 10). Then, the control unit 60 controls the irradiation position of the laser light L such that the laser light L is irradiated in the vicinity of the boundary BA corresponding to the base of the triangular area AA, on a portion where the semiconductor chip 1 remains supported by the support substrate 10.

### Effects of First Embodiment

The effects of the first embodiment will be described next.

As described above, in the first embodiment, the control unit 60 controls the irradiation position of the laser light L such that, as viewed from a direction perpendicular to the surface 10b of the support substrate 10, the laser light L is irradiated from one end 1a side of the semiconductor chip 1 to the other end 1b side while moving relative to the support substrate 10. Here, the effects of the adhesive force of the adhesive layer 2 are smaller when the semiconductor chip 1 is peeled from an edge than when the semiconductor chip 1 is peeled from the center. The foregoing is because, at the center, the periphery of the portion to be peeled is in contact with the adhesive layer 2, while, at the edge, the adhesive layer 2 exists only on one side of the portion to be peeled. Therefore, as a result of the control unit 60 controlling the irradiation position of the laser light L to move from one end 1a side of the semiconductor chip 1 to the other end 1b side, peeling begins from an end of the semiconductor chip 1, making it possible to easily peel the semiconductor chip 1.

As described above, in the first embodiment, it is set in accordance with the fragility of the semiconductor chip 1 to be transferred. As a result, even if the semiconductor chip 1 is relatively fragile, such as the semiconductor chip 1 with a relatively small thickness t1, the area of the spot area SA of the laser light L is set in accordance with the fragility of the semiconductor chip 1. For example, when the semiconductor chip 1 is relatively fragile, the area of the spot area of the laser light is adjusted to be relatively small. As a result of the area of the spot area SA of the laser light L becoming relatively small, deformation of the adhesive layer 2 also becomes small. As a result, stress that acts on the semiconductor chip 1 caused by the deformation of the adhesive layer 2 is reduced, making it possible to prevent the semiconductor chip 1 from being damaged. As a result, it is possible to transfer the semiconductor chip 1 while suppressing damage to the semiconductor chip 1 caused by deformation of the adhesive layer 2.

In addition, in the first embodiment, as described above, the laser light irradiation unit 70 is configured to irradiate the laser light L intermittently when the laser light L is irradiated while moving relative to the support substrate 10. The control unit 60 controls the irradiation position of the laser light L that is intermittently irradiated so as to irradiate the vicinity of the boundary BA between a portion where the semiconductor chip 1 has peeled from the support substrate 10 due to the irradiation of the laser light L and a portion where the semiconductor chip 1 remains supported by the support substrate 10. Here, the effect of the holding force of the adhesive layer 2 in the vicinity of the boundary BA becomes smaller than the effect of the holding force at unpeeled portions away from the vicinity of the boundary BA. The foregoing is because, while the periphery of portions to be peeled is in contact with the adhesive layer 2 except in the vicinity of the boundary BA, the adhesive layer 2 exists only on one side of portions to be peeled in the vicinity of the boundary BA. As a result, it is possible to easily peel the semiconductor chip 1 by irradiating the vicinity of the boundary BA with the laser light L.

In addition, in the first embodiment, as described above, the control unit 60 adjusts the pitch pt of the irradiation positions of the laser light L that is intermittently irradiated to be small at the ends of the semiconductor chip 1 and to be large at the center of the semiconductor chip 1. Here, it has been confirmed through experiments and simulations carried out by the present inventor that the area of the semiconductor chip 1 that is peeled by a single irradiation of laser light L becomes larger at the ends of the semiconductor chip 1 than at the center of the semiconductor chip 1. In addition, it has been confirmed that irradiating laser light L onto a portion of the semiconductor chip 1 that has already peeled does not contribute to further peeling. That is, since the area of the semiconductor chip 1 that is peeled by a single laser irradiation is large at the ends, when subsequently irradiating laser light L to the center of the semiconductor chip 1, the pitch pt of the irradiation positions of the laser light L can be increased to more efficiently transfer the element. Thus, the control unit 60 adjusts the pitch pt of the irradiation positions of the laser light L that is intermittently irradiated to be small at the ends of the semiconductor chip 1 and to be large at the center of the semiconductor chip 1, thereby reducing the time required for the transfer of the semiconductor chip 1, compared to a case in which the pitch pt of the irradiation positions of the laser light L is decreased across the entire semiconductor chip 1.

Additionally, in the first embodiment, as described above, the pitch pt of the irradiation positions of the laser light L that is intermittently irradiated is set to become smaller as the semiconductor chip 1 becomes more fragile. Here, when the area of the spot area SA of the laser light L is set to decrease as the semiconductor chip 1 becomes more fragile, if the pitch pt of the irradiation positions of the laser light L remains relatively large, the distance between the portions of the semiconductor chip 1 peeled from the adhesive layer 2 becomes large, and the holding force of the adhesive layer 2 with respect to the entire semiconductor chip 1 remains relatively large. Therefore, by setting the pitch pt of the irradiation positions of the laser light L to decrease as the semiconductor chip 1 becomes more fragile, the distance between the portions of the semiconductor chip 1 peeled from the adhesive layer 2 becomes small, thereby reducing the holding force of the adhesive layer 2 with respect to the entire semiconductor chip 1. As a result, the semiconductor chip 1 can be appropriately peeled from the adhesive layer 2.

### Second Embodiment

A semiconductor chip transfer device 100a according to a second embodiment will be described next. In the second embodiment, the area of the spot area SA is adjusted by the control unit 60 in accordance with the thickness t1 of the semiconductor chip 1. The semiconductor chip transfer device 100a is one example of an “element transfer device” in the present disclosure.

As shown in FIG. 10, the semiconductor chip transfer device 100a comprises a storage unit 201. The storage unit 201 stores, in advance, information on the appropriate area of the spot area SA of the laser light L with respect to the thickness t1 of the semiconductor chip 1. An appropriate area with respect to the thickness t1 of the semiconductor chip 1 is determined through experiments and simulations.

The other configurations of the second embodiment are the same as those of the first embodiment described above.

### (Semiconductor Chip Transfer Method)

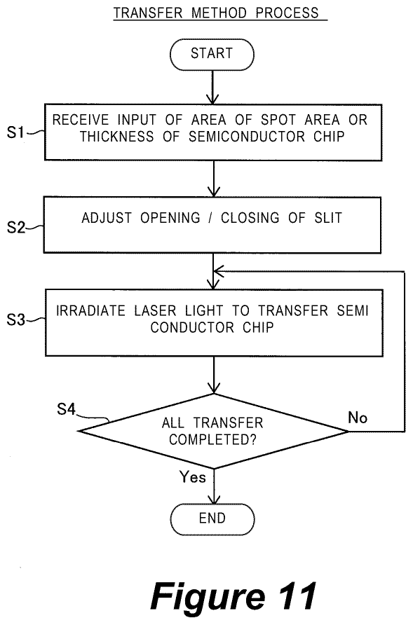

A semiconductor chip transfer method according to the second embodiment will be described next with reference to FIG. 11.

In step S1, a control unit 60a receives input of the area of the spot area SA. Alternatively, the control unit 60a receives input of the thickness t1 of the semiconductor chip 1. The input is executed by an operator.

In step S2, the control unit 60a adjusts the opening and closing of the slit 74 on the basis of the area of the spot area SA that has been input. Alternatively, the control unit 60a adjusts the opening and closing of the slit 74 on the basis of the thickness t1 of the semiconductor chip 1 that has been input, and the appropriate area of the spot area SA of the laser light L with respect to the thickness t1 of the semiconductor chip 1 stored in the storage unit 201.

In step S3, the control unit 60a irradiates laser light L toward the support substrate 10 supporting the semiconductor chip 1 via the adhesive layer 2, from a side (Z1 side) opposite to the surface 10a of the support substrate 10 supporting the semiconductor chip 1. Here, in the second embodiment, in the step for irradiating laser light L, the area of the spot area SA of the laser light L is set to be smaller than the area of a surface 1c of the semiconductor chip 1 supported by the support substrate 10, and set in accordance with the fragility of the semiconductor chip 1 to be transferred. Specifically, the laser light L is adjusted and irradiated such that the area of the spot area SA of the laser light L becomes smaller as the thickness t1 of the semiconductor chip 1 decreases. As described above, the control unit 60a controls the galvanometer mirror 72 such that the irradiation of laser light L is started from the corner 1d of the semiconductor chip 1. Thereafter, the control unit 60 controls the galvanometer mirror 72 such that the irradiation position of the laser light L moves to a corner diagonally opposite to the corner 1d, while causing the laser light L to follow a zigzag pattern. In addition, the control unit 60a controls the laser light irradiation unit 70 to intermittently irradiate the laser light L.

In step S4, the control unit 60a determines whether all of a plurality of the semiconductor chips 1 supported on the support substrate 10 have been transferred. If no in step S4, the process returns to step S3. If yes in step S4, the semiconductor chip 1 transfer operation ends.

### Effects of Second Embodiment

The effects of the second embodiment will be described next.

In the second embodiment, as described above, the area of the spot area SA is adjusted (changed) in accordance with the thickness t1 of the semiconductor chip 1. It is thereby possible to transfer a plurality of types of the semiconductor chips 1 having various thicknesses.

### Third Embodiment

A semiconductor chip transfer device 100b (refer to FIG. 1) according to a third embodiment will be described next. The configurations of the semiconductor chip transfer device 100b of the third embodiment other than a control unit 60b are the same as those of the first embodiment.

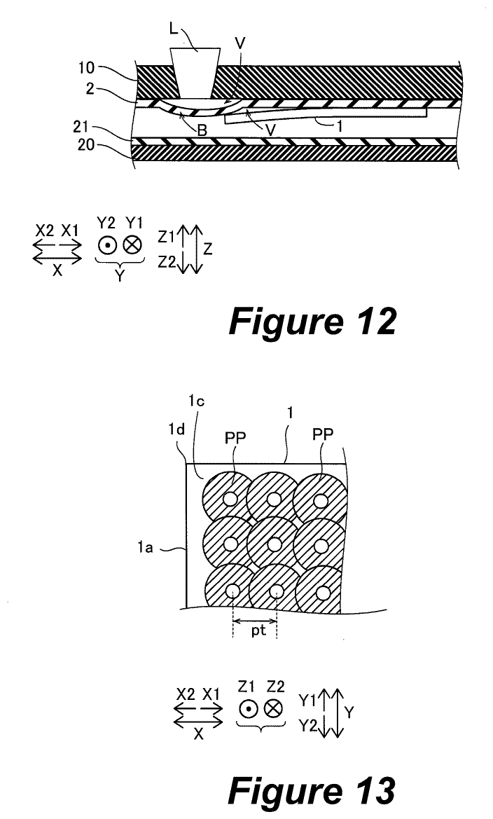

In the semiconductor chip transfer device 100b of the third embodiment, as shown in FIG. 12, the control unit 60b starts irradiation of the laser light L such that only a portion of the blister B that is generated due to the laser light L being irradiated on the adhesive layer 2 overlaps with the semiconductor chip 1, as viewed from a direction perpendicular to the front surface (surface 10b) of the support substrate 10. Specifically, the control unit 60b irradiates the laser light L so as not to overlap with the semiconductor chip 1 as viewed from a direction perpendicular to the front surface of the support substrate 10. As a result, only the ends of the blister B on the X1 side overlap with the ends of the semiconductor chip 1 on the X2 side. In addition, gaps V are generated by the blister B respectively between the support substrate 10 and the adhesive layer 2, and between the adhesive layer 2 and the semiconductor chip 1. Thereafter, in the same manner as in the first embodiment, the control unit 60b controls the irradiation position of the laser light L such that the laser light L is irradiated from one end 1a side of the semiconductor chip 1 to the other end 1b side while moving relative to the support substrate 10.

### Effect of Third Embodiment

The effects of the third embodiment will be described next.

In the third embodiment, as described above, the control unit 60b starts irradiation of the laser light L such that only a portion of the blister B that is generated due to the laser light L being irradiated on the adhesive layer 2 overlaps with the semiconductor chip 1, as viewed from a direction perpendicular to the front surface of the support substrate 10. Here, when the semiconductor chip 1 begins to be peeled, the entire surface of the semiconductor chip 1 is in close contact with the adhesive layer 2. Therefore, when laser light is irradiated on a position where the entire blister B overlaps with the semiconductor chip 1, the total adhesive force acting on the semiconductor chip 1 becomes large, which increases the bending stress acting on the semiconductor chip 1 and may cause damage to the semiconductor chip 1. Therefore, by irradiating the laser light L on a position where only a portion of the blister B overlaps with the semiconductor chip 1, the total adhesive force acting on the semiconductor chip 1 can be reduced, which reduces the bending stress acting on the semiconductor chip 1, thereby suppressing damage to the semiconductor chip 1.

### Fourth Embodiment

A semiconductor chip transfer device 100c (refer to FIG. 1) according to a fourth embodiment will be described next. The configurations of the semiconductor chip transfer device 100c of the fourth embodiment other than a control unit 60c are the same as those of the first embodiment.

In the semiconductor chip transfer device 100c of the fourth embodiment, as shown in FIG. 13, the laser light irradiation unit 70 is configured to irradiate laser light L intermittently when the laser light L is irradiated moving relative to the support substrate 10. Then, the control unit 60c controls the irradiation position of the laser light L that is intermittently irradiated such that portions PP of the semiconductor chip 1 that have peeled from the support substrate 10 due to the intermittently irradiated laser light L overlap with each other. Specifically, the laser light L is intermittently irradiated at intervals of the pitch pt. Then, by irradiation of the laser light L, for example, circular (annular) portions PP of the semiconductor chip 1 are peeled. The irradiation position of the laser light L is controlled such that the peeled circular portions PP partially overlap with each other. In addition, even if gaps form between a plurality of peeled portions PP, the portions of the semiconductor chip 1 that correspond to the gaps naturally are peeled as the adjacent portions PP are peeled, so that the semiconductor chip 1 can be peeled even with intermittent irradiation of the laser light L.

### Effect of Fourth Embodiment

The effects of the fourth embodiment will be described next.

In the fourth embodiment, as described above, the laser light irradiation unit 70 is configured to irradiate laser light L intermittently when the laser light L is irradiated while moving relative to the support substrate 10. Then, the control unit 60c controls the irradiation position of the laser light L that is intermittently irradiated such that portions PP of the semiconductor chip 1 that have peeled from the support substrate 10 due to the intermittently irradiated laser light L overlap with each other. As a result, since the peeled portions PP of the semiconductor chip 1 overlap with each other, the semiconductor chip 1 can be peeled even with intermittent irradiation of the laser light L.

### Fifth Embodiment

A semiconductor chip transfer device 100d (refer to FIG. 1) according to a fifth embodiment will be described next. The configurations of the semiconductor chip transfer device 100d of the fifth embodiment other than a control unit 60d are the same as those of the first embodiment.

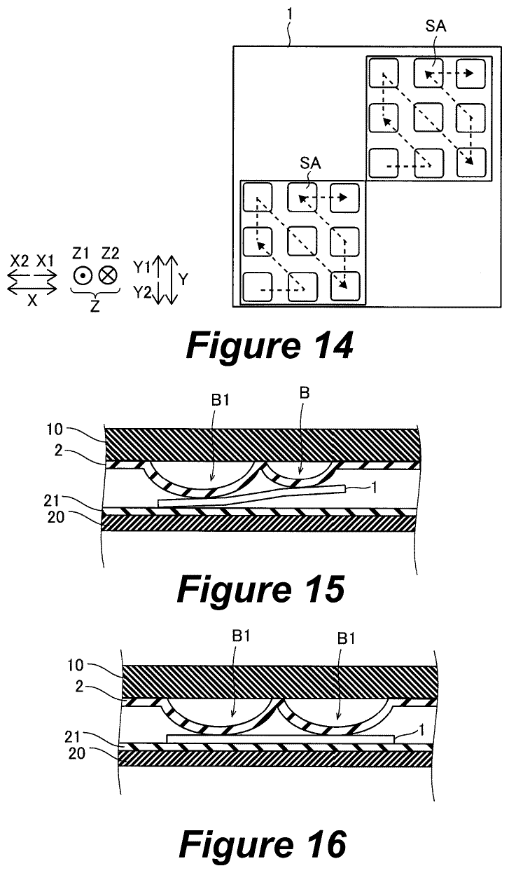

As shown in FIGS. 14 to 16, in the semiconductor chip transfer device 100d according to the fifth embodiment, the control unit 60d controls the irradiation position of the laser light L that is intermittently irradiated such that small blisters B that are generated on the adhesive layer 2 due to the intermittently irradiated laser light L coalesce with each other to form a single large blister B1. For example, as shown in FIG. 14, the control unit 60d controls the irradiation position of the laser light L such that the irradiation position of the laser light L moves following a zigzag pattern with respect to a rectangular region on the semiconductor chip 1. The control unit 60d causes the laser light L to be intermittently irradiated while the laser light L follows a zigzag pattern. As a result, as shown in FIG. 15, a small blister B is formed by a single irradiation of the laser light L, and blisters B that have been formed coalesce with each other, forming a single large blister B1. This large blister B1 causes the semiconductor chip 1 to reach the adhesive layer 21 of the receiving substrate 20, as shown in FIG. 16.

### Effect of Fifth Embodiment

The effects of the fifth embodiment will be described next.

In the fifth embodiment, as described above, the control unit 60d controls the irradiation position of the laser light L that is intermittently irradiated such that small blisters B that are generated on the adhesive layer 2 due to the intermittently irradiated laser light L coalesce with each other to form a single large blister B1. As a result, since the blisters B coalesce with each other to form a single large blister B1, the semiconductor chip 1 can be peeled even with intermittent irradiation of the laser light L. In addition, since blisters B that are generated by the laser light L are small, the stress acting on the semiconductor chip 1 can be reduced. As a result, damage to the semiconductor chip 1 can be further suppressed.

### Sixth Embodiment

A semiconductor chip transfer device 100e (refer to FIG. 1) according to a sixth embodiment will be described next. In the semiconductor chip transfer device 100e according to the sixth embodiment, the method for determining the spot area SA of the laser light L is different from that of the first embodiment. The other configurations of the semiconductor chip transfer device 100e are the same as those of the first embodiment.

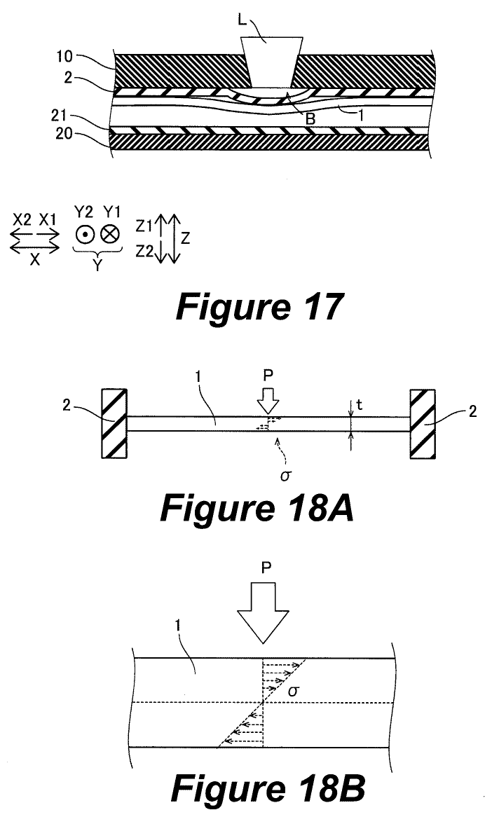

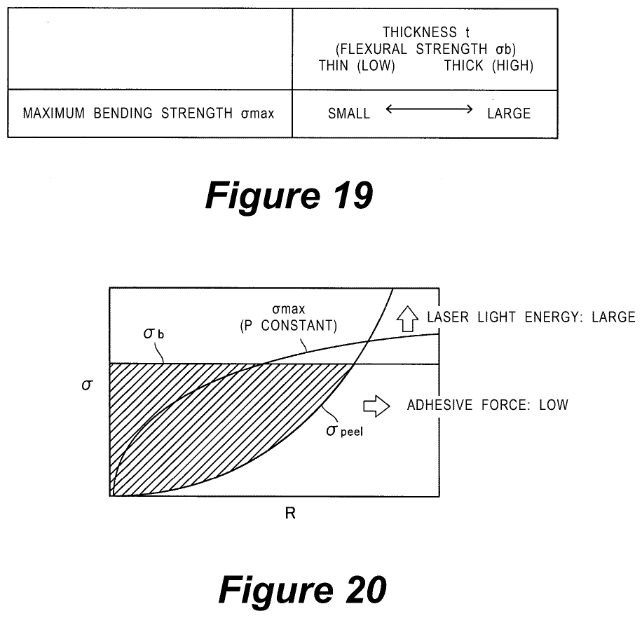

FIG. 18A shows a model of the adhesive layer 2 and the semiconductor chip 1 for a case in which the adhesive layer 2 is irradiated with laser light L, thereby generating a blister B (FIG. 17). In this model, the thickness of the semiconductor chip 1 is t, and the force with which the semiconductor chip 1 is pressed by the blister B is P. In addition, the adhesive force of the adhesive layer 2 acts on the semiconductor chip 1 in a direction opposite to that of the pressing force of the blister B, and bending stress σ is generated in the semiconductor chip 1. Specifically, as shown in FIG. 18B, the force P generates internal stress (bending stress) σ that is perpendicular to the cross section of the semiconductor chip 1. The bending stress σ increases closer to the front surface of the semiconductor chip 1. The maximum bending stress σ is defined as σmax. Then, in the semiconductor chip transfer device 100d according to the sixth embodiment, the minimum stress applied to the semiconductor chip 1 when being peeled from the adhesive layer 2 is σpeel, the force with which the blister B, generated due to the laser light L being irradiated on the adhesive layer 2, presses the element is P, the radius of the peeled range of the semiconductor chip 1 is R, the thickness of the semiconductor chip 1 is t, Poisson's ratio is ν, and the maximum bending stress σmax applied to the semiconductor chip 1 is defined as σmax=P×(1+ν)×(0.485×ln(R/t)+0.52)/t². Then, when σb is defined as the flexural strength of the semiconductor chip 1, P and R are set such that σpeel<σmax<σb is satisfied by adjusting the area and energy of the spot area SA of the laser light L. The formula for σmax is a formula for calculating the maximum stress of a disk when concentrated load is applied to the center of the disk. Here, the thickness t of the semiconductor chip 1 and Poisson's ratio ν are values that are dependent on the shape and material of the semiconductor chip 1. The P and R are set so as to satisfy the relationship described above by adjusting the spot size and energy of the laser light L. In addition, when the relationship P=kπR² is satisfied, σpeel is obtained, which is the condition under which the semiconductor chip 1 is peeled. It should be noted that k is a value dependent on the adhesive force of the adhesive layer 2. As shown in FIG. 19, the maximum bending stress σmax increases as the thickness t of the semiconductor chip 1 increases. In addition, the maximum bending stress σmax increases as the flexural strength σb of the semiconductor chip 1 increases.

As shown in FIG. 20, a graph is created in which the horizontal axis is R and the vertical axis is σ (σpeel, σmax, σb). The hatched area surrounded by σpeel and σb is the region in which the above-mentioned relationship (σpeel<σmax<σb) is satisfied. The graph shows that a smaller R provides a larger margin for peeling the semiconductor chip 1 without damage. In addition, the curve of σmax moves upward as the energy of the laser light L increases. Additionally, the curve of σpeel moves rightward as the adhesive force of the adhesive layer 2 decreases. In the semiconductor chip transfer device 100e, P and R that satisfy the above-mentioned relationship may be set manually, or be set automatically by the semiconductor chip transfer device 100e.

### Effect of Sixth Embodiment

The effects of the sixth embodiment will be described next.

In the sixth embodiment, the P and R are set so as to satisfy the relationship described above. As a result, it is possible to easily adjust the area and energy of the spot area SA of the laser light L so that damage to the semiconductor chip 1 can be suppressed, on the basis of the relationship described above.

### Seventh Embodiment

A semiconductor chip transfer device 100f (refer to FIG. 1) according to a seventh embodiment will be described next. The configurations of the semiconductor chip transfer device 100f of the seventh embodiment other than a control unit 60f are the same as those of the first embodiment.

The control unit 60f of the semiconductor chip transfer device 100f of the seventh embodiment selects any of the semiconductor chips 1 within a transfer area and controls the laser light irradiation unit 70 to irradiate laser light L thereon, thereby transferring only the semiconductor chip 1 within the transfer area onto the receiving substrate 20. In addition, the control unit 60f acquires a predicted transfer position A1 on the receiving substrate 20 to which the semiconductor chip 1 will be transferred on the basis of at least the distance d1 between the support substrate 10 and the receiving substrate 20, and the length l1 of the semiconductor chip 1 along the X direction. In addition, the control unit 60f compares the predicted transfer position A1 with a vertical transfer position A to which the semiconductor chip 1 would be transferred if dropped in the Z2 direction without being moved in the X and Y directions to thereby acquire a positional deviation amount p of the transfer position. Additionally, the control unit 60f controls the movement mechanism 50 such that the support substrate holding part 30 and/or the receiving substrate holding part 40 is moved on the basis of the acquired positional deviation amount p.

### (Semiconductor Chip Transfer Method)

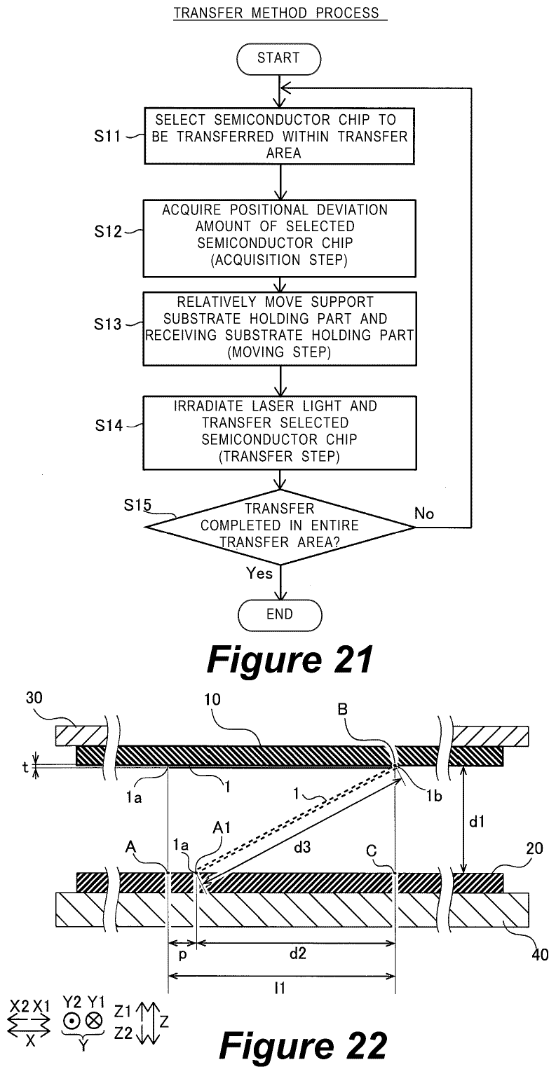

A semiconductor chip 1 transfer method according to the seventh embodiment will be described next with reference to FIGS. 21 to 27. The process of the semiconductor chip 1 transfer method described below is executed by the control unit 60f.

In step S11 shown in FIG. 21, in the semiconductor chip 1 transfer step to be executed this time, the semiconductor chip 1 to be transferred is selected, the semiconductor chip 1 being supported on the support substrate 10. The support substrate 10 and the receiving substrate 20 are placed opposite each other so as to transfer the selected semiconductor chip 1 onto the receiving substrate 20. Then, the process proceeds to step S12.

In step S12 of the seventh embodiment, the control unit 60f acquires the predicted transfer position A1 on the receiving substrate 20 to which the semiconductor chip 1 will be transferred, on the basis of at least the distance d1 between the support substrate 10 and the receiving substrate 20, and the length l1 of the semiconductor chip 1 along the X direction. Then, the predicted transfer position A1 is compared with the vertical transfer position A to which the semiconductor chip 1 would be transferred if dropped in the Z2 direction without being moved in the X and Y directions, to thereby acquire the positional deviation amount p of the transfer position.

The specific method for acquiring the positional deviation amount p will be described with reference to FIG. 22. FIG. 22 is a side view (XZ cross-sectional view) of the semiconductor chip transfer device 100f of FIG. 1 as viewed from the Y2 direction. The semiconductor chip 1 indicated by the broken lines in FIG. 22 shows the state of the semiconductor chip 1 immediately before being completely peeled from the support substrate 10. The predicted transfer position A1 is set to the position where one end 1a of the semiconductor chip 1 on the X2 direction side irradiated with the laser light L comes in contact with the receiving substrate 20. At this time, the other end 1b of the semiconductor chip 1 is not peeled from the support substrate 10, but is in a state of being in contact with and supported at position B. As a result, the semiconductor chip 1 is in a tilted state in which one end 1a, and the other end 1b above (in the Z1 direction) the one end 1a, are supported. In addition, the position on the receiving substrate 20 located vertically below (in the Z2 direction) position B on the support substrate 10 is defined as position C. At this time, a right triangle having the positions A1, B, and C as vertices can be drawn on an XZ cross section shown in FIG. 22.

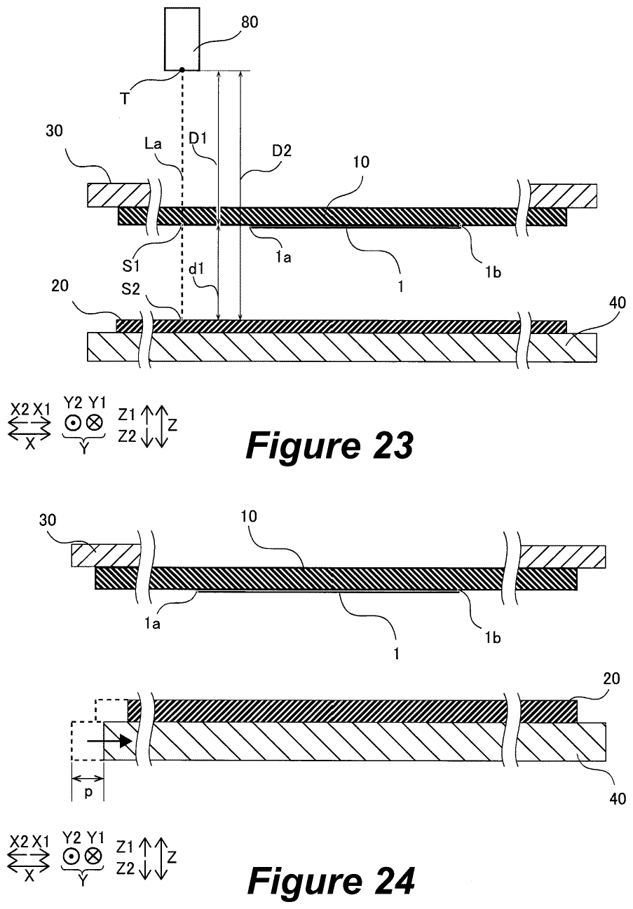

At this time, the control unit 60f acquires the thickness t of the semiconductor chip 1, the length l1 of the semiconductor chip 1 along the X direction, and the distance d1 between the support substrate 10 and the receiving substrate 20. In the seventh embodiment, the control unit 60f acquires the thickness t of the semiconductor chip 1 and the length l1 of the semiconductor chip 1 along the X direction, which are known in advance. In addition, in the seventh embodiment, as shown in FIG. 23, the control unit 60f acquires the distance d1 between the support substrate 10 and the receiving substrate 20 on the basis of data measured using a laser displacement meter 80 attached above (in the Z1 direction) of the support substrate 10. As shown in FIG. 23, the laser displacement meter 80 irradiates laser light La toward the support substrate 10 and, using a measurement method such as white light interferometry, measures, as a first distance D1, the distance between a reference position T and a given position S1 on the surface of the support substrate 10 on the side that supports the semiconductor chip 1. In addition, the laser displacement meter 80 irradiates laser light La toward the support substrate 10 and acquires, as a second distance D2, the distance between the reference position T and a position S2 on the surface of the receiving substrate 20 on the side to which the semiconductor chip 1 is transferred, located vertically below (in the Z2 direction) the position S1. Then, the laser displacement meter 80 is configured to acquire the difference between the measured first distance D1 and second distance D2 as the distance d1 between the support substrate 10 and the receiving substrate 20.

When the thickness t of the semiconductor chip 1 is small enough to ignore compared to the distance d1 between the support substrate 10 and the receiving substrate 20, a distance d3 between position B and position A1 on the right triangle having the positions A1, B, and C as vertices, can be regarded as the length l1 of the semiconductor chip 1 along the X direction. As a result, by using Pythagoras's theorem on the basis of the length l1 of the hypotenuse and the distance d1 of one side, the control unit 60f calculates the distance d2 between positions A1 and Cas d2=√(l1²−d1²). In addition, the control unit 60f acquires the positional deviation amount p between the predicted transfer position A1 and the vertical transfer position A to which the semiconductor chip 1 would be transferred if dropped vertically downward (in the Z2 direction) without being moved in the X and Y directions, as p=l1−d2. Then, the process proceeds to step S13.

In step S13 of the seventh embodiment, the support substrate 10 and/or the receiving substrate 20 is moved on the basis of the positional deviation amount p. For example, as shown in FIG. 24, the control unit 60f controls the movement mechanism 50 to move a receiving substrate holding mechanism to a position shifted in the X1 direction by an amount equivalent to the positional deviation amount p acquired in advance. Then, the process proceeds to step S14.

In step S14 of the seventh embodiment, as viewed from the Z direction perpendicular to the front surface of the support substrate 10, the laser light L is irradiated from one end 1a side of the semiconductor chip 1 to the other end 1b side while moving relative to the support substrate 10. As a result, the semiconductor chip 1 supported by the support substrate 10 is peeled from the X1 side, and one end 1a of the semiconductor chip 1 on the X2 direction side comes in contact with, and is supported by, the receiving substrate 20 before the entire semiconductor chip 1 is peeled from the support substrate 10. At this time, the other end 1b of the semiconductor chip 1 is not peeled from the support substrate 10, but is in a state of being in contact with and supported at position B. As a result, transfer of the semiconductor chip 1 is started in a tilted state in which one end 1a, and the other end 1b above (in the Z1 direction) the one end 1a are supported, after which the entire semiconductor chip 1 is transferred.

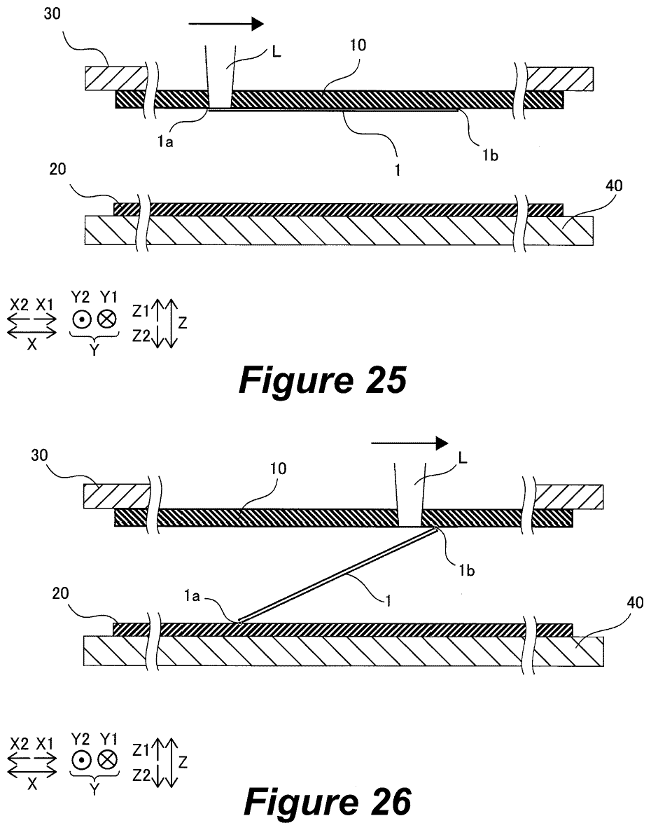

Specifically, the control unit 60f adjusts the galvanometer mirror 72 and causes the laser light irradiation unit 70 to irradiate laser light L. As shown in FIG. 25, as a result of the laser light L being irradiated onto the semiconductor chip 1 from a surface on the side opposite to the surface of the support substrate 10 supporting the semiconductor chip 1, an undiagrammed adhesive layer formed on the support substrate 10 is decomposed from the one end 1a side on the X2 direction side where the laser light L is irradiated. Therefore, the semiconductor chip 1 is peeled from the one end 1a side on the X2 direction side.

In addition, as shown in FIG. 26, when the laser light L is moved relatively in the X1 direction, one end 1a of the semiconductor chip 1 on the X2 direction side comes in contact with, and is supported by, the receiving substrate 20 before the entire semiconductor chip 1 is peeled from the support substrate 10. At this time, the other end 1b of the semiconductor chip 1 is not peeled from the support substrate 10, but is in a state of being in contact with and supported at position B. As a result, transfer of the semiconductor chip 1 is started in a tilted state in which one end 1a, and the other end 1b above (in the Z1 direction) the one end 1a are supported, after which the entire semiconductor chip 1 is transferred. As a result, the semiconductor chip 1 is transferred to a position shifted in the X1 direction relative to the position A to which the semiconductor chip 1 would be transferred if dropped in the Z2 direction without being moved in the X and Y directions.

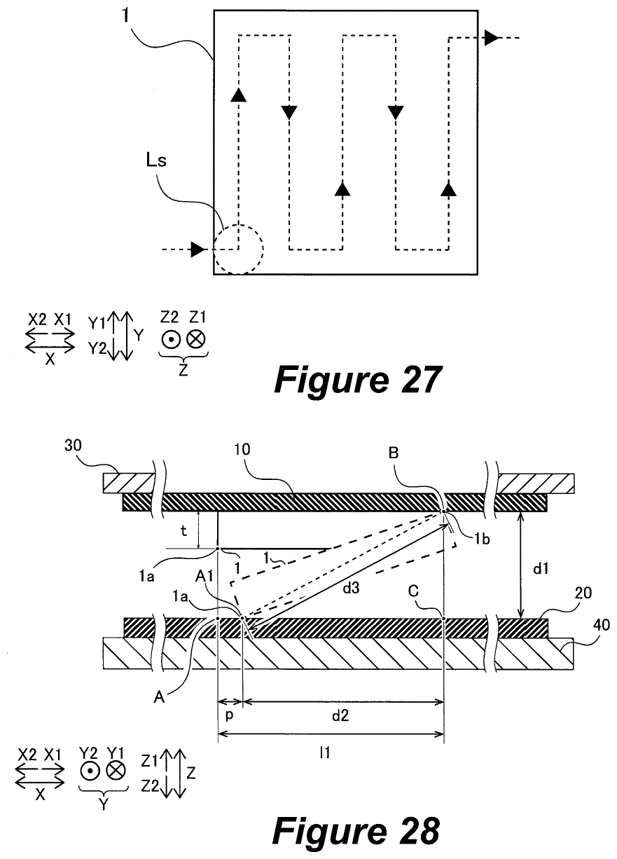

In addition, in step S14 of the seventh embodiment, as shown in FIG. 27, the area of a spot area Ls of the laser light is set to be smaller than the area of the surface of the semiconductor chip 1 supported by the support substrate 10. Then, the control unit 60f controls the laser light L to move while following a zigzag pattern on the surface of the semiconductor chip 1, when the laser light L is irradiated moving relative to the support substrate 10 in the X1 direction. For example, as shown in FIG. 27, the control unit 60f controls the laser light L to move relatively in the X1 direction while following a zigzag pattern along the dotted line with arrows. Then, the process proceeds to step S15.

In step S15, the control unit 60f determines whether the transfer of the semiconductor chips 1 to the receiving substrate 20 has been completed in all of a plurality of transfer areas that have been arranged. If it is determined that the transfer of the semiconductor chips 1 to the receiving substrate 20 has been completed in all of the plurality of transfer areas that have been arranged (Yes in step S15), the process ends, and if it is determined the transfer of the semiconductor chips 1 to the receiving substrate 20 has not been completed in all of the plurality of transfer areas that have been arranged (No in step S15), the process returns to step S11. By repeating this series of processes, in the seventh embodiment, the control unit 60f controls the laser light L to be irradiated moving relative to the support substrate 10 in the X1 direction, with respect to all of the semiconductor chips 1 to be transferred supported on the support substrate 10. For example, as shown in FIG. 2, when the support substrate 10 is supporting a plurality of the semiconductor chips 1 in a horizontal plane (in the XY plane), the control unit 60f selects one of the semiconductor chips 1 and controls the laser light L to be irradiated moving relative to the selected semiconductor chip 1 in the X1 direction, thereby transferring the semiconductor chip 1 to a position shifted in the X1 direction. The control unit 60f is configured to then select another semiconductor chip 1 and carry out the same process. By repeating the foregoing process, the laser light L is irradiated moving relative to the support substrate 10 in the X1 direction, with respect to all of the semiconductor chips 1 to be transferred supported on the support substrate 10.

### Effect of Seventh Embodiment

The effects of the seventh embodiment will be described next.

The semiconductor chip transfer device 100f and the semiconductor chip 1 transfer method of the seventh embodiment comprise the support substrate holding part 30 that holds a support substrate 10 on which at least one semiconductor chip 1 is supported, the laser light irradiation unit 70 that is disposed on a side opposite to the surface on which the semiconductor chip 1 is supported by the support substrate 10 and that irradiates laser light L toward the support substrate 10, and the control unit 60f that controls at least the irradiation position of the laser light L irradiated from the laser light irradiation unit 70. The control unit 60f controls the laser light L such that, as viewed from a direction perpendicular to the front surface of the support substrate 10, the laser light L is irradiated in the X1 direction from one end 1a side of the semiconductor chip 1 to the other end 1b side while moving relative to the support substrate 10. As a result, the semiconductor chip 1 supported on the support substrate 10 is peeled from the one end 1a side on the X2 direction side, and one end 1a of the semiconductor chip 1 on the X2 direction side comes in contact with the receiving substrate 20 before the entire semiconductor chip 1 is peeled from the support substrate 10, so that the entire semiconductor chip 1 is transferred. As a result, one end 1a of the semiconductor chip 1 on the X2 direction side comes in contact with the receiving substrate 20 fixing the position thereof, after which the remaining portion is peeled. Therefore, the direction of the shift in the transfer position of the semiconductor chip 1 is controlled to be in a set direction, thereby making it possible to suppress the transfer positions of the semiconductor chips 1 on the receiving substrate 20 from being scattered in various directions (variation in the transfer positions can be suppressed).

According to the semiconductor chip transfer device 100f and the semiconductor chip 1 transfer method of the seventh embodiment, the area of the spot area Ls of the laser light is smaller than the area of the surface of the semiconductor chip 1 supported by the support substrate 10, and the control unit 60f controls the laser light L to be irradiated moving relative to the support substrate 10 in the X1 direction, following a zigzag pattern on the surface of the semiconductor chip 1. As a result, it becomes easier to irradiate only a desired position compared to a case in which the area of the spot area Ls of the laser light is larger than the area of the surface of the semiconductor chip 1, so that it becomes easier to partially peel the semiconductor chip 1 from the desired portion. As a result, it is possible to cause the semiconductor chip 1 to come in contact with, and to be transferred to, the receiving substrate 20 from the desired portion (one end 1a of the semiconductor chip 1 on the X2 direction side). In addition, the laser light L is moved relatively in the X1 direction following a zigzag pattern, so that the laser light L can be irradiated over the entire surface of the semiconductor chip 1.

In addition, in the seventh embodiment, the control unit 60f acquires the predicted transfer position A1 on the receiving substrate 20 to which the semiconductor chip 1 will be transferred on the basis of at least the distance d1 between the support substrate 10 and the receiving substrate 20, and the length l1 of the semiconductor chip 1 along the X direction. Then, the control unit 60f compares the predicted transfer position A1 with the vertical transfer position A to which the semiconductor chip 1 would be transferred if dropped in the Z2 direction without being moved in the X and Y directions, to thereby acquire, in advance, the positional deviation amount p of the transfer position. As a result, it is possible to identify, in advance, the amount of positional deviation that occurs between the actual transfer position and the vertical transfer position A to which the semiconductor chip 1 would be transferred if dropped in the Z2 direction without being moved in the X and Y directions, before the semiconductor chip 1 is actually transferred to the receiving substrate 20.

In addition, in the seventh embodiment, the semiconductor chip transfer device 100f further comprises the receiving substrate holding part 40 that holds the receiving substrate 20 to which the semiconductor chip 1 is transferred, and the movement mechanism 50 that moves the support substrate holding part 30 and/or the receiving substrate holding part 40. Then, the control unit 60f controls the movement mechanism 50 such that the support substrate holding part 30 and/or the receiving substrate holding part 40 is moved on the basis of the acquired positional deviation amount p. As a result, it becomes possible to adjust, in advance and before the transfer, the positions of the support substrate 10 and the receiving substrate 20 such that positional deviation does not occur between the actual transfer position and the vertical transfer position A to which the semiconductor chip 1 would be transferred if dropped in the Z2 direction without being moved in the X and Y directions. As a result, the semiconductor chip 1 can be transferred to a desired position.

In addition, in the seventh embodiment, the support substrate 10 held by the support substrate holding part 30 supports a plurality of the semiconductor chips 1, and the control unit 60f is configured to control the laser light L to be irradiated moving relative to the support substrate 10 in the X1 direction, with respect to all of the semiconductor chips 1 to be transferred supported on the support substrate 10. As a result, one ends 1a of all of the semiconductor chips 1 to be transferred on the X2 direction side, the semiconductor chips 1 being supported on the support substrate 10, can all be brought into contact with the receiving substrate 20 from the same direction (X1 direction). Therefore, the direction of the shift in the transfer positions of the semiconductor chips 1 is controlled to be in a set direction, thereby making it possible to suppress the transfer positions of the semiconductor chips 1 on the receiving substrate 20 from being scattered in various directions (variation in the transfer positions can be suppressed).

### Eighth Embodiment

A semiconductor chip transfer device 100g (refer to FIG. 1) and the semiconductor chip 1 transfer method according to an eighth embodiment will be described next, with reference to FIG. 28. The device configuration of the semiconductor chip transfer device 100g is the same as the device configuration of the semiconductor chip transfer device 100 shown in FIG. 1, except for a control unit 60g. In the eighth embodiment, an example will be described in which the thickness t of the semiconductor chip 1 cannot be ignored compared to the distance d1 between the support substrate 10 and the receiving substrate 20, unlike in the above-mentioned seventh embodiment in which the thickness t of the semiconductor chip 1 can be ignored compared to the distance d1 between the support substrate 10 and the receiving substrate 20. Descriptions of features of the eighth embodiment that are the same as those of the seventh embodiment will be omitted.

In the eighth embodiment, the control unit 60g is configured to acquire the predicted transfer position A1 on the receiving substrate 20 to which the semiconductor chip 1 is transferred on the basis of the thickness t of the semiconductor chip 1, in addition to the distance d1 between the support substrate 10 and the receiving substrate 20 and the length l1 of the semiconductor chip 1 along the X direction, and compare the predicted transfer position A1 with the vertical transfer position A to which the semiconductor chip 1 would be transferred if dropped in the Z direction without being moved in the X and Y directions, to thereby acquire, in advance, the positional deviation amount p of the transfer position.

In the eighth embodiment as well, the semiconductor chip 1 indicated by the broken lines shows a state of the semiconductor chip 1 immediately before being completely peeled from the support substrate 10. The predicted transfer position A1 is set to the position where one end 1a of the semiconductor chip 1 on the X2 direction side irradiated with the laser light L comes in contact with the receiving substrate 20. At this time, the other end 1b is not peeled from the support substrate 10, but is in a state of being supported at position B. In addition, the position on the receiving substrate 20 located vertically below (in the Z2 direction of FIG. 28) position B on the support substrate 10 is defined as position C. At this time, a right triangle having the positions A1, B, and C as vertices can be drawn on the XZ cross section shown in FIG. 28.

When the thickness t of the semiconductor chip 1 cannot be ignored compared to the distance d1 between the support substrate 10 and the receiving substrate 20, the distance d3 between position B and position A1 on the right triangle having the positions A1, B, and C as vertices is first calculated. The distance d3 between the positions B and A1 is a diagonal line in the XZ cross section of the semiconductor chip 1. Therefore, the control unit 60g uses Pythagoras's theorem on the basis of the thickness t of the semiconductor chip 1 and the length l1 of the semiconductor chip 1 in the X direction to acquire the distance d3 between the positions B and A1 as d3=√(t²+l1²).

Subsequently, the control unit 60g uses Pythagoras's theorem on the basis of the distance d3 between the positions B and A1 and the distance d1 between the support substrate 10 and the receiving substrate 20, and the control unit 60g calculates the distance d2 between the positions A1 and C as d2=√(d3²−d1²). In addition, the control unit 60g acquires the positional deviation amount p between the predicted transfer position A1 and the vertical transfer position A to which the semiconductor chip 1 would be transferred if dropped in the Z direction without being moved in the X and Y directions, as p=l1−d2.

### Effect of Eighth Embodiment

The effects of the eighth embodiment will be described next.

In the eighth embodiment, the control unit 60g acquires the predicted transfer position A1 on the receiving substrate 20 to which the semiconductor chip 1 will be transferred on the basis of the thickness t of the semiconductor chip 1, in addition to the distance d1 between the support substrate 10 and the receiving substrate 20, and the length l1 of the semiconductor chip 1 along the X direction. Then, the control unit 60g compares the predicted transfer position A1 with the vertical transfer position A to which the semiconductor chip 1 would be transferred if dropped in the Z2 direction without being moved in the X and Y directions, to thereby acquire, in advance, the positional deviation amount p of the transfer position. As a result, even when the thickness t of the semiconductor chip 1 is too large to ignore relative to the distance d1 between the support substrate 10 and the receiving substrate 20, it becomes possible to accurately identify, in advance, the amount of positional deviation that occurs between the actual transfer position and the vertical transfer position A to which the semiconductor chip 1 would be transferred if dropped in the Z2 direction without being moved in the X and Y directions.

The other effects of the eighth embodiment are the same as those of the seventh embodiment described above.

### Ninth Embodiment

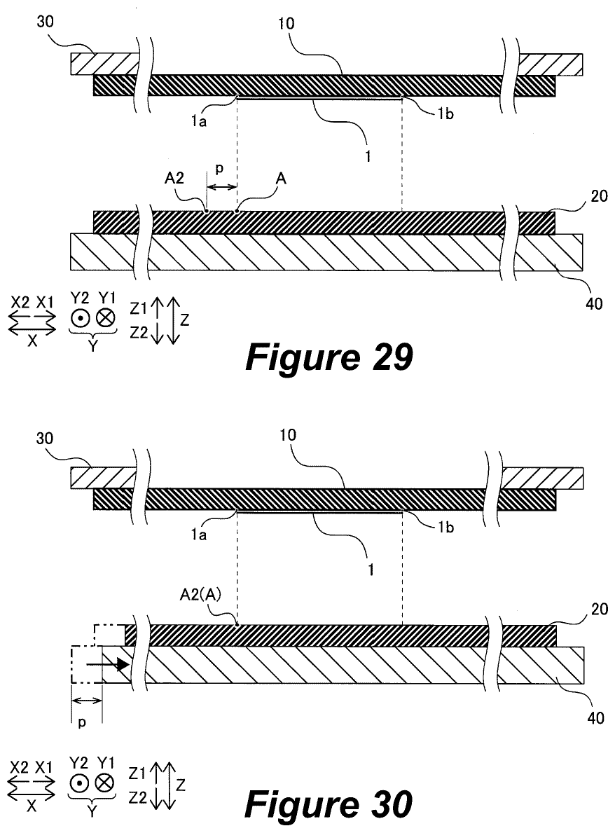

A semiconductor chip transfer device 100h (refer to FIG. 1) and the semiconductor chip 1 transfer method according to a ninth embodiment will be described next, with reference to FIGS. 29 and 30. The device configuration of the semiconductor chip transfer device 100h is the same as the device configuration of the semiconductor chip transfer device 100 shown in FIG. 1, except for a control unit 60h. In the ninth embodiment, another example will be described in which the control unit 60h causes the movement mechanism 50 to move the support substrate holding part 30 and/or the receiving substrate holding part 40 on the basis of the positional deviation amount p. Descriptions of features of the ninth embodiment that are the same as the seventh or eighth embodiments will be omitted.

In the ninth embodiment, the control unit 60h acquires, on the basis of the positional deviation amount p, a target transfer position A2 that is shifted from the vertical transfer position A by an amount equal to the positional deviation amount p. Then, the control unit 60h controls the movement mechanism 50 to move the support substrate holding part 30 and/or the receiving substrate holding part 40 such that the target transfer position A2 is positioned directly below the position of the semiconductor chip 1 to be transferred (that is, such that the vertical transfer position A and the target transfer position A2 overlap).

In the ninth embodiment as well, as shown in FIG. 22, the control unit 60h acquires the predicted transfer position A1 on the receiving substrate 20 to which the semiconductor chip 1 will be transferred on the basis of at least the distance d1 between the support substrate 10 and the receiving substrate 20, and the length l1 of the semiconductor chip 1 along the X direction. Then, the predicted transfer position A1 is compared with the vertical transfer position A to which the semiconductor chip 1 would be transferred if dropped in the Z2 direction without being moved in the X and Y directions, to thereby acquire the positional deviation amount p of the transfer position.

In addition, as shown in FIG. 29, the control unit 60h acquires the target transfer position A2 on the front surface of the receiving substrate 20, on the basis of the acquired positional deviation amount p. At this time, the control unit 60h acquires the target transfer position A2 such that a position shifted from the vertical transfer position A in the X2 direction by the positional deviation amount p becomes the target transfer position A2.

Subsequently, as shown in FIG. 30, the control unit 60h controls the movement mechanism 50 to move the support substrate holding part 30 and/or the receiving substrate holding part 40 such that the target transfer position A2 is positioned in the Z2 direction of the semiconductor chip 1 supported by the support substrate 10 (that is, such that the vertical transfer position A and the target transfer position A2 overlap).

### Effect of Ninth Embodiment

The effects of the ninth embodiment will be described next.

In the ninth embodiment, the control unit 60h acquires, on the basis of the positional deviation amount p, the target transfer position A2 that is shifted from the vertical transfer position A by an amount equal to the positional deviation amount p, and controls the movement mechanism 50 to move the support substrate holding part 30 and/or the receiving substrate holding part 40 such that the target transfer position A2 is positioned in the Z2 direction of the semiconductor chip 1 to be transferred (that is, such that the vertical transfer position A and the target transfer position A2 overlap). As a result, the support substrate holding part 30 and/or the receiving substrate holding part 40 can be moved in advance on the basis of the target transfer position A2 that takes the positional deviation amount p into consideration, so that it is possible to carry out transfer without causing positional deviation.

### Modified Example

It should be noted that the embodiments disclosed above are examples in all respects and should not be construed as restrictive. The scope of the present invention is defined not by the above description of the embodiments but by the claims, and further includes the meaning that is equivalent that of the claims, as well as all modifications (modified examples) within the scope thereof.

For example, in the first to the sixth embodiments, examples are shown in which the semiconductor chip 1 is peeled as a result of deformation of the adhesive layer 2, but the present invention is not limited thereto. For example, the present invention can be applied to a semiconductor chip transfer device in which the adhesive layer 2 is gasified and the semiconductor chip 1 is peeled by the pressure of the gas.

In addition, in the first to the sixth embodiments, examples are shown in which the control unit 60 controls the irradiation position of the laser light L such that the laser light L is irradiated from one end 1a side of the semiconductor chip 1 to the other end 1b side while moving relative to the support substrate 10, but the present invention is not limited thereto. For example, the control unit 60 may control the irradiation position of the laser light L such that the irradiation position of the laser light L is started from the center of the semiconductor chip 1.

In addition, in the first and second embodiments, examples are shown in which the control unit 60 adjusts the pitch pt of the irradiation positions of the laser light L that is intermittently irradiated to be small at the ends of the semiconductor chip 1 and to be large at the center of the semiconductor chip 1, but the present invention is not limited thereto. For example, the control unit 60 may adjust the irradiation positions such that the pitch pt of the irradiation positions of the laser light L that is intermittently irradiated becomes constant.

In addition, in the first to the ninth embodiments, examples are shown in which the shape of the support substrate 10 is circular and the shape of the receiving substrate 20 is rectangular, but the present invention is not limited thereto. For example, the shapes of the support substrate 10 and the receiving substrate 20 may both be circular or polygonal.

In addition, in the first to the ninth embodiments, examples are shown in which the laser light irradiation unit 70 has the laser light source 71, the galvanometer mirror 72, and the f-θ lens 73, but the invention is not limited thereto. For example, a polygon mirror may be used instead of the galvanometer mirror 72, or a mask may be used instead of the galvanometer mirror 72 and the f-θ lens 73.

In addition, in the first to the sixth embodiments, examples are shown in which the entire surface 1c of the semiconductor chip 1 is supported when the semiconductor chip 1 is supported on the support substrate 10 via the adhesive layer 2, but the present invention is not limited thereto. For example, the semiconductor chip 1 may partially include a convex portion, and be configured such that only the convex portion of the semiconductor chip 1 is supported by the support substrate 10 via the adhesive layer 2, such as in a blister chip.

In addition, in the first to the ninth embodiments, examples are shown in which the present invention is applied to a semiconductor chip 1 as the element of the present invention, but the present invention is not limited thereto. The present invention may be applied to an element other than a semiconductor chip 1.

In addition, in the second embodiment, an example is shown in which the thickness t1 is input as the fragility of the semiconductor chip 1, but the present invention is not limited thereto. In the present invention, an input other than the thickness t1 may be accepted as the fragility of the semiconductor chip 1.

In addition, in the third embodiment, an example is shown in which the control unit 60b irradiates the laser light L so as not to overlap with the semiconductor chip 1 as viewed from a direction perpendicular to the front surface of the support substrate 10, but the present invention is not limited thereto. For example, the control unit 60b may irradiate the laser light L so as to partially overlap with the semiconductor chip 1 as viewed from a direction perpendicular to the front surface of the support substrate 10, such that only a portion of a blister B that is generated due to irradiation of the laser light L on the adhesive layer 2 overlaps with the semiconductor chip 1.

In addition, in the fourth embodiment, an example is shown in which gaps are generated between peeled portions PP of the semiconductor chip 1, but the present invention is not limited thereto. For example, the laser light L may be irradiated such that gaps are not generated between the peeled portions PP of the semiconductor chip 1.

In addition, in the fifth embodiment, an example is shown in which the semiconductor chip 1 is caused to reach the adhesive layer 21 of the receiving substrate 20 by a large blister B1, but the present invention is not limited thereto. For example, the semiconductor chip 1 may reach the adhesive layer 21 of the receiving substrate 20 by falling from the large blister B1 due to its own weight.

In addition, in the sixth embodiment, an example is shown in which the formula for the maximum bending strength σmax that acts on the semiconductor chip 1 is a formula for calculating the maximum stress of a disk when concentrated load is applied to the center of the disk, but the present invention is not limited thereto. For example, the formula for the maximum bending stress σmax may be a formula for calculating the maximum stress of a disk when a load is applied to the disk in an annular shape.

In addition, in the first to the ninth embodiments, examples are shown in which the area of the spot area Ls of the laser light is smaller than the area of the semiconductor chip 1 that is supported by the support substrate 10, but the present invention is not limited thereto. For example, the area of the spot area Ls of the laser light may be larger than or equal to the area of the semiconductor chip 1 supported by the support substrate 10.

In addition, in the first to the ninth embodiments, examples are shown in which the laser light L is configured to be controlled to move while following a zigzag pattern on the surface of the semiconductor chip 1 when being irradiated moving relative to the support substrate 10 in the X1 direction, but the present invention is not limited thereto. For example, the area of the spot area Ls of the laser light may be made larger than the area of the semiconductor chip 1 supported by the support substrate 10, and the laser light may be controlled to be irradiated moving relatively in the X1 direction without following a zigzag pattern.

In addition, in the first to the ninth embodiments, examples are shown in which the entire surface of the semiconductor chip 1 is supported when the semiconductor chip 1 is supported on the support substrate 10 via the adhesive layer, but the present invention is not limited thereto. For example, the semiconductor chip 1 may partially include a convex portion, and be configured such that only the convex portion of the semiconductor chip 1 is supported by the support substrate 10 via the adhesive layer, such as in a blister chip.

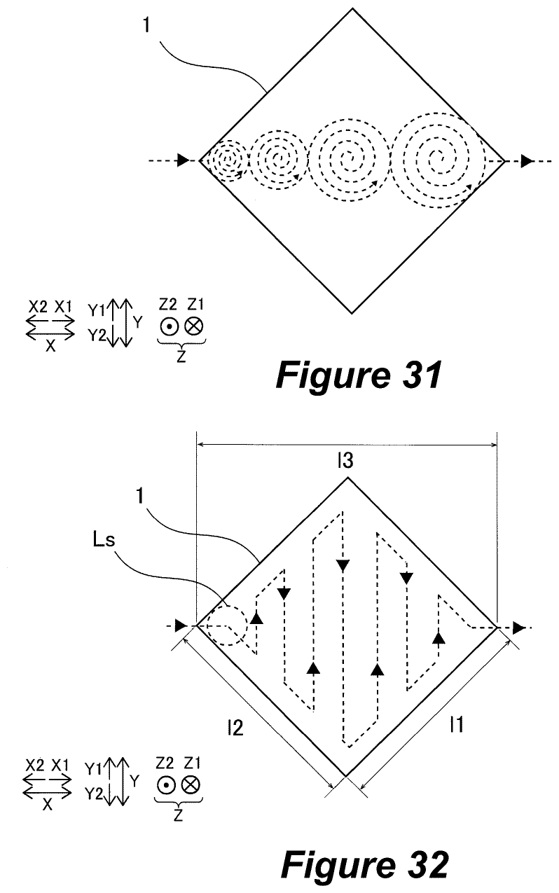

In addition, in the first to the ninth embodiments, examples are shown in which the laser light L is controlled to move while following a zigzag pattern on the surface of the semiconductor chip 1 when being irradiated moving relative to the support substrate 10 in the X1 direction, but the present invention is not limited thereto. For example, when only a convex portion of the semiconductor chip 1 is supported by the support substrate 10 via an adhesive layer, such as in a blister chip, the laser light L may be controlled to rotate in a spiral shape and move relatively in the X1 direction so as to draw a plurality of circles having different sizes in accordance with the size of the area to be peeled, as shown in FIG. 31.

In addition, in the first to the ninth embodiments, examples are shown in which the direction of the relative movement of the laser light L is from the X2 direction to the X1 direction with respect to all of the semiconductor chips 1 to be transferred, but the present invention is not limited thereto. The direction of the relative movement of the laser light L may be any direction from one end 1a side of the semiconductor chip 1 to the other end 1b side as viewed from the Z direction with respect to the front surface of the support substrate 10. For example, the direction may be controlled to be from the Y1 direction to the Y2 direction.

In addition, in the seventh to the ninth embodiments, examples are shown in which known values are acquired when the control units 60f, 60g, and 60h acquire the thickness t of the semiconductor chip 1 and the length l1 of the semiconductor chip 1 along the X direction, but the present invention is not limited thereto. For example, the values respectively acquired by the control units 60f, 60g, and 60h may be acquired by measurements using the laser displacement meter 80, or acquired by direct measurements using a micrometer, or the like.

In addition, in the seventh to the ninth embodiments, examples are shown in which a value obtained by a measurement using the laser displacement meter 80 is acquired when the control units 60f, 60g, and 60h acquire the distance d1 between the support substrate 10 and the receiving substrate 20, but the present invention is not limited thereto. For example, the value respectively acquired by the control units 60f, 60g, and 60h may be acquired as a value known to an operator, or acquired by direct measurement using a micrometer, or the like.

In addition, in the seventh to the ninth embodiments, examples are shown in which the length l1 of one side of the semiconductor chip 1 is arranged along the X direction, whereby the positional deviation amount p is acquired on the basis of the length l1 of one side of the semiconductor chip 1, but the present invention is not limited thereto. For example, when the diagonal of the semiconductor chip 1 is arranged along the X direction, as shown in FIG. 32, the positional deviation amount p may be configured to be acquired on the basis of the length 13 of the diagonal of the semiconductor chip 1.

In addition, in the seventh to the ninth embodiments, examples are shown in which, when acquiring the predicted position, the control units 60f, 60g, and 60h acquire the predicted transfer position A1 on the receiving substrate 20 to which the semiconductor chip 1 is transferred on the basis of at least the distance d1 between the support substrate 10 and the receiving substrate 20 and the length l1 of the semiconductor chip 1 along the X direction, and compare the predicted transfer position A1 with the vertical transfer position A to which the semiconductor chip 1 would be transferred if dropped vertically without being moved in the horizontal direction, to thereby acquire, in advance, the positional deviation amount p of the transfer position, but the present invention is not limited thereto. For example, the control units 60f, 60g, and 60h may be configured to carry out a test transfer under the same conditions as the actual transfer before carrying out the actual transfer, to acquire the transfer position on the receiving substrate 20 to which the semiconductor chip 1 would be transferred, which is compared with the vertical transfer position A to which the semiconductor chip 1 would be transferred if dropped vertically without being moved in the horizontal direction, to thereby acquire, in advance, the positional deviation amount p of the transfer position.

In addition, in the seventh to the ninth embodiments, a configuration is shown in which the positional deviation amount p is acquired, but the present invention is not limited thereto. For example, it may be configured such that, instead of acquiring the positional deviation amount p, laser light L is controlled to be irradiated moving relative to the support substrate 10 in the X1 direction, whereby the semiconductor chip 1 supported by the support substrate 10 is peeled from one end 1a side, and the one end 1a of the semiconductor chip 1 on the X2 direction side comes in contact with the receiving substrate 20 before the entire semiconductor chip 1 is peeled from the support substrate 10, so that the entire semiconductor chip 1 is transferred.

In addition, in the seventh to the ninth embodiments, examples are shown in which the control units 60f, 60g, and 60h control the movement mechanism 50 to move the receiving substrate holding part 40, but the present invention is not limited thereto. For example, the control units 60f, 60g, and 60h may be configured to control the movement mechanism 50 to move both the receiving substrate holding part 40 and the support substrate holding part 30, or configured to move only the support substrate holding part 30.

In addition, in the seventh to the ninth embodiments, a configuration is shown in which the receiving substrate holding part 40 and the support substrate holding part 30 are moved on the basis of the positional deviation amount p, but the present invention is not limited thereto. For example, when the acquired positional deviation amount p is small enough so as not to affect the desired transfer position accuracy, transfer may be carried out without moving the receiving substrate holding part 40 and the support substrate holding part 30.

What is claimed is:

1. An element transfer device, comprising:
a support substrate holding part configured to hold a support substrate on which an element is supported via an adhesive layer;
a laser light irradiation unit disposed on a side opposite to a surface on which the element is supported by the support substrate and configured to irradiate laser light toward the support substrate; and
a control unit configured to control an irradiation position of the laser light irradiated from the laser light irradiation unit,
an area of a spot area of the laser light being smaller than an area of a surface of the element supported by the support substrate, and
the control unit being configured to control the irradiation position of the laser light such that, as viewed from a direction perpendicular to a front surface of the support substrate, the laser light is irradiated from one end side of the element to the other end side while moving relative to the support substrate.

2. The element transfer device according to claim 1, wherein
the area of the spot area of the laser light is set in accordance with fragility of the element to be transferred.

3. The element transfer device according to claim 2, wherein
the laser light irradiation unit is configured to intermittently irradiate the laser light when the laser light is irradiated while moving relative to the support substrate, and
a pitch of irradiation positions of the laser light that is intermittently irradiated is set to become smaller as the element becomes more fragile.

4. The element transfer device according to claim 1, wherein
the laser light irradiation unit is configured to intermittently irradiate the laser light when the laser light is irradiated while moving relative to the support substrate, and
the control unit is configured to control the irradiation position of the laser light that is intermittently irradiated so as to irradiate a vicinity of a boundary between a portion where the element is peeled from the support substrate due to irradiation of the laser light and a portion where the element remains supported by the support substrate.

5. The element transfer device according to claim 4, wherein
the control unit is configured to adjust a pitch of irradiation positions of the laser light that is intermittently irradiated to be small at ends of the element and to be large at a center of the element.

6. The element transfer device according to claim 1, wherein
the control unit is configured to control the laser light to be irradiated while the laser light moves relative to the support substrate in a first direction from one end side of the element to the other end side as viewed from a direction perpendicular to the front surface of the support substrate, such that the element supported by the support substrate is peeled from the one end side, and one end of the element comes in contact with a receiving substrate before entirety of the element is peeled from the support substrate, after which the entirety of the element is transferred.

7. The element transfer device according to claim 6, wherein
the control unit is configured to control the laser light to be irradiated while the laser light moves relative to the support substrate in the first direction, following a zigzag pattern on the surface of the element.

8. The element transfer device according to claim 6, further comprising
a receiving substrate holding part configured to hold the receiving substrate to which the element is transferred, and
a movement mechanism configured to move at least one of the support substrate holding part and the receiving substrate holding part,
the control unit being further
configured to acquire a predicted transfer position on the receiving substrate to which the element is transferred,
configured to compare the predicted transfer position with a vertical transfer position to which the element is transferred when dropped vertically without being moved in a horizontal direction, to thereby acquire, in advance, a positional deviation amount of a transfer position, and
configured to control the movement mechanism such that the at least one of the support substrate holding part and the receiving substrate holding part is moved on the basis of the positional deviation amount.

9. The element transfer device according to claim 8, wherein
the control unit is
configured to acquire, on the basis of the positional deviation amount, a target transfer position that is shifted from the vertical transfer position by an amount equal to the positional deviation amount, and
configured to control the movement mechanism to move the at least one of the support substrate holding part and the receiving substrate holding part such that a target transfer position is positioned directly below the element to be transferred.

10. The element transfer device according to claim 8, wherein
the control unit is
configured to acquire the predicted transfer position on the receiving substrate to which the element is transferred on the basis of at least a distance between the support substrate and the receiving substrate and a length of the element along the first direction, and
configured to compare the predicted transfer position with the vertical transfer position to which the element is transferred when dropped vertically without being moved in the horizontal direction, to thereby acquire, in advance, the positional deviation amount of the transfer position.

11. The element transfer device according to claim 10, wherein
the control unit is
configured to acquire the predicted transfer position on the receiving substrate to which the element is transferred further on the basis of a thickness of the element, and
configured to compare the vertical transfer position and the predicted transfer position, to thereby acquire, in advance, the positional deviation amount.

12. The element transfer device according to claim 6, wherein
the support substrate held by the support substrate holding part is configured to support a plurality of elements, and
the control unit is configured to control the laser light to be irradiated while the laser light moves relative to the support substrate in the first direction, with respect to all of the elements to be transferred supported on the support substrate.

13. The element transfer device according to claim 1, wherein
the control unit is configured to start irradiation of the laser light such that only a portion of a blister that is generated due to the laser light being irradiated on the adhesive layer overlaps with the element, as viewed from a direction perpendicular to the front surface of the support substrate.

14. The element transfer device according to claim 1, wherein
the laser light irradiation unit is configured to intermittently irradiate the laser light when the laser light is irradiated while moving relative to the support substrate, and
the control unit is configured to control the irradiation position of the laser light that is intermittently irradiated such that portions of the element that have been peeled from the support substrate due to the intermittently irradiated laser light overlap with each other.

15. The element transfer device according to claim 1, wherein
the control unit is configured to control the irradiation position of the laser light that is intermittently irradiated such that small blisters that are generated on the adhesive layer due to the intermittently irradiated laser light coalesce with each other to form a single large blister.

16. The element transfer device according to claim 1, wherein
a force with which a blister, generated due to the laser light being irradiated on the adhesive layer, presses the element and a radius of a peeled range of the element are set such that σpeel<σmax<σb is satisfied by adjusting the area and energy of the spot area of the laser light, where
σpeel represents a minimum stress applied to the element when being peeled from the adhesive layer,
σmax represents a maximum bending stress applied to the element and is defined as σmax=P×(1+ν)×(0.485×ln(R/t)+0.52)/t², where
P represents the force with which the blister, generated due to the laser light being irradiated on the adhesive layer, presses the element,
R represents the radius of the peeled range of the element,
t represents a thickness of the element, and
ν represents Poisson's ratio, and
σb represents flexural strength of the element.

17. An element transfer method, comprising:
irradiating laser light toward a support substrate on which an element is supported via an adhesive layer from a side opposite to a surface on which the element is supported by the support substrate,
the irradiating of the laser light including
adjusting the laser light such that an area of a spot area of the laser light is smaller than an area of a surface of the element supported by the support substrate, and
irradiating the laser light such that, as viewed from a direction perpendicular to a front surface of the support substrate, the laser light is irradiated from one end side of the element to the other end side while moving relative to the support substrate.

18. The element transfer method according to claim 17, wherein,
the laser light is irradiated while moving relative to the support substrate in a first direction from the one end side of the element to the other end side as viewed from the direction perpendicular to the front surface of the support substrate, such that the element supported by the support substrate is peeled from the one end side of the element, and one end of the element comes in contact with, and is transferred to, a receiving substrate before entirety of the element is peeled from the support substrate.

19. The element transfer device according to claim 18, further comprising
acquiring a predicted transfer position on the receiving substrate to which the element is transferred on the basis of at least a distance between the support substrate and the receiving substrate and a length of the element along the first direction, and
comparing the predicted transfer position with a vertical transfer position to which the element is transferred when dropped vertically without being moved in a horizontal direction, to thereby acquire a positional deviation amount of a transfer position.

20. The element transfer method according to claim 19, wherein
the acquiring of the predicted transfer position further includes acquiring, on the basis of a thickness of the element, the predicted transfer position on the receiving substrate to which the element is transferred.

21. The element transfer method according to claim 20, further comprising
relatively moving the support substrate and the receiving substrate by moving at least one of the support substrate and the receiving substrate on the basis of the positional deviation amount.

22. The element transfer method according to claim 21, further comprising
acquiring a target transfer position that is shifted from the vertical transfer position by an amount equal to the positional deviation amount on the basis of the positional deviation amount,
the moving of the at least one of the support substrate and the receiving substrate includes moving the at least one of the support substrate and the receiving substrate such that the target transfer position is positioned directly below the element to be transferred.
